(19) United States
(12) Patent Application Publication
(10) Pub. No.: US 2013/0248998 A1
(43) Pub. Date: Sep. 26, 2013

(54) SEMICONDUCTOR DEVICE

(71) Applicants: Shinichiro Misu, Tokyo (JP); Tsuyoshi Ota, Hyogo-ken (JP); Tatsuya Nishiwaki, Hyogo-ken (JP); Takeshi Uchihara, Saitama-ken (JP); Yusuke Kawaguchi, Kanagawa-ken (JP)

(72) Inventors: Shinichiro Misu, Tokyo (JP); Tsuyoshi Ota, Hyogo-ken (JP); Tatsuya Nishiwaki, Hyogo-ken (JP); Takeshi Uchihara, Saitama-ken (JP); Yusuke Kawaguchi, Kanagawa-ken (JP)

(73) Assignee: Kabushiki Kaisha Toshiba, Tokyo (JP)

(21) Appl. No.: 13/619,336

(22) Filed: Sep. 14, 2012

(30) Foreign Application Priority Data
Mar. 23, 2012 (JP) 2012-068433

(51) Int. Cl. H01L 29/78

(52) U.S. Cl. CPC H01L 29/7801
USPC 257/335

(57) ABSTRACT

According to one embodiment, a semiconductor device includes, a drain, source, base and drift regions, a gate electrode, a gate insulating film, a first semiconductor region, a drain electrode, and a source electrode. The drain region has a first portion, and a second portion having a surface extending in a first direction which is vertical to a main surface of the first portion. The source region extends in a second direction which is parallel to the second portion, and is provided to be spaced from the drain region. The gate electrode extends in the first direction and a third direction which is vertical to the first direction and the second direction, and passes through the base region in the third direction. The first semiconductor region is provided between the gate insulating film and the drain region, and has a lower impurity concentration than the drift region.

### CROSS-REFERENCE TO RELATED APPLICATIONS

This application is based upon and claims the benefit of priority from the prior Japanese Patent Application No. 2012-068433, filed on Mar. 23, 2012; the entire contents of which are incorporated herein by reference.

### FIELD

Embodiments described herein relate generally to a semiconductor device.

### BACKGROUND

A metal oxide semiconductor field effect transistor (MOSFET) is desired to operate at a lower driving voltage and to have a low resistance, in addition to control a large electric current and to have a high breakdown voltage.

A three-dimensional type MOSFET in which a channel region is formed in a vertical direction of a semiconductor substrate in addition to a main surface of the semiconductor substrate is advantageous for reducing an on-resistance. In the three-dimensional MOSFET, there is provided a drain layer which has a first portion and a second portion provided vertically to the first portion, a drift region which is provided in parallel to the second portion, a base region, a source region, and a gate electrode which is extended in a vertical direction to the second portion. In the three-dimensional type MOSFET mentioned above, a further improvement of the breakdown voltage is desired.

### BRIEF DESCRIPTION OF THE DRAWINGS

FIG. 1 is a schematic perspective view of a semiconductor device according to a first embodiment;

FIGS. 2A to 2B are schematic cross sectional views of the semiconductor device according to the first embodiment;

FIGS. 3A to 3B are schematic views of a semiconductor device according to a second embodiment;

FIGS. 4A to 4B are schematic views of a semiconductor device according, to a variation of the second embodiment;

FIGS. 5A to 5C are schematic views illustrating a semiconductor device according to a third embodiment;

FIGS. 6A to 6C are schematic cross sectional views showing variations of the third embodiment;

FIGS. 7A to 7B are schematic views illustrating a semiconductor device according to a fourth embodiment;

FIGS. 8A to 8C are schematic top elevational views showing variations of the fourth embodiment;

FIGS. 9A to 9B are schematic perspective views illustrating a semiconductor device according to a fifth embodiment;

FIG. 10 is a schematic perspective view illustrating a semiconductor device according to a sixth embodiment;

FIG. 11A to FIG. 14B are schematic perspective views illustrating the manufacturing method (first one) of the semiconductor device;

FIGS. 15A to 16C are schematic perspective views illustrating the manufacturing method (second one) of the semiconductor device;

FIGS. 17A to 21C are schematic perspective views illustrating the manufacturing method (third one) of the semiconductor device;

FIG. 22A to FIG. 24B are schematic perspective views illustrating a manufacturing method (fourth one) of a semiconductor device according to an embodiment, and

FIG. 25A to FIG. 26B are schematic perspective views illustrating a manufacturing method (fifth one) of a semiconductor device according to an embodiment.

### DETAILED DESCRIPTION

In general, according to one embodiment, a semiconductor device includes: a drain region of a first conductivity type which has a first portion, and a second portion having a surface extending in a first direction which is vertical to a main surface of the first portion; a source region of the first conductivity type which extends in a second direction which is parallel to the second portion, and is provided to be spaced from the drain region; a base region of a second conductivity type which is provided between the drain region and the source region so as to be in contact with the source region; a drift region of the first conductivity type which is provided between the drain region and the base region; a gate electrode which extends in the first direction and a third direction which is vertical to the first direction and the second direction, and passes through the base region in the third direction; a gate insulating film which is provided between the source region, the base region and the drift region, and the gate electrode; a first semiconductor region which is provided between the gate insulating film and the drain region, and has a lower impurity concentration than the drift region; a drain electrode which is connected to the drain region; and a source electrode which is connected to the source region and the base region.

According to another embodiment, a semiconductor device includes: a drain region of a first conductivity type which has a first portion, and a second portion having a surface extending in a first direction which is vertical to a main surface of the first portion; a source region of the first conductivity type which extends in a second direction which is parallel to the second portion, and is provided so as to be spaced from the drain region; a base region of a second conductivity type which is provided between the drain region and the source region so as to be in contact with the source region; a drift region of the first conductivity type which is provided between the drain region and the base region; a gate electrode which extends in the first direction and a third direction which is vertical to the first direction and the second direction, and passes through the base region in the third direction; a gate insulating film which is provided between the source region, the base region and the drift region, and the gate electrode; a field plate configuration portion which is provided between the gate insulating film and the drain region; a drain electrode which is connected to the drain region; and a source electrode which is connected to the source region and the base region, wherein the field plate configuration portion includes: a first field plate electrode which is provided between the gate electrode and the first portion; and a first field plate insulating film which is provided between the first field plate electrode and the drift region.

A description will be given below of an embodiment of the invention with reference to the accompanying drawings.

In this case, the drawings are schematic or conceptual, and a relationship between a thickness and a width in each of the portions, and a ratio coefficient of a magnitude between the portions are not necessarily identical to actual ones. Further, even in the case of showing the same portion, there is a case that the mutual dimensions and the ratio coefficient are differently shown according to the drawings.

Further, in the specification and each of the drawings, the same reference numerals are attached to the same element as mentioned above with regard to the previously provided drawings, and a detailed description thereof will be appropriately omitted.

Further, in the following description, a specific example in which a first conductivity type is an n-type and a second conductivity type is set to a p-type is listed up as one example.

Further, reference symbols n⁺, n and n⁻ and p⁺, p and p⁻ denote relative heights of an impurity concentration in each of the conductivity types. In other words, n⁺ indicates that the n-type impurity concentration is relatively higher than n, and n⁻ and n⁻⁻ indicate that the n-type impurity concentration is relatively lower than n and n⁻, respectively. Further, p⁺ indicates that the p-type impurity concentration is relatively higher than p, and p⁻ and p⁻⁻ indicate that the p-type impurity concentration is relatively lower than p and p⁻, respectively.

### First Embodiment

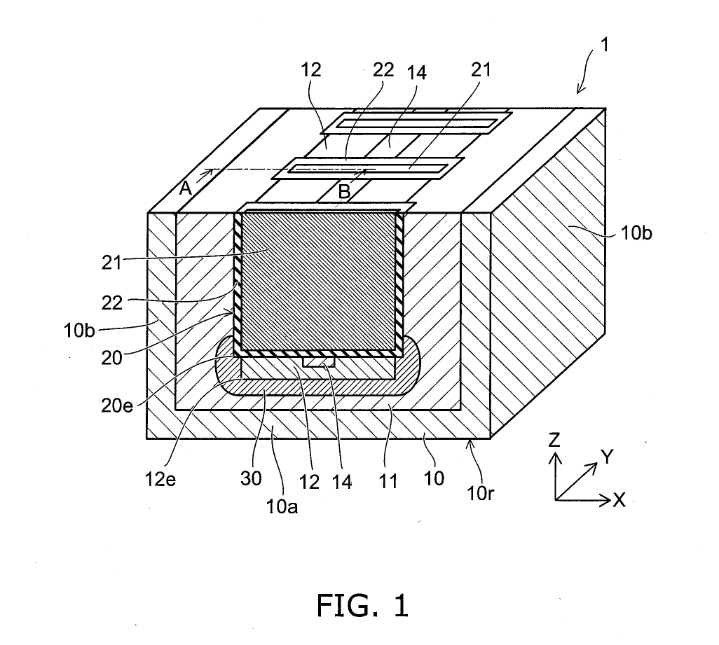

FIG. 1 is a schematic perspective view semiconductor device according to a first embodiment.

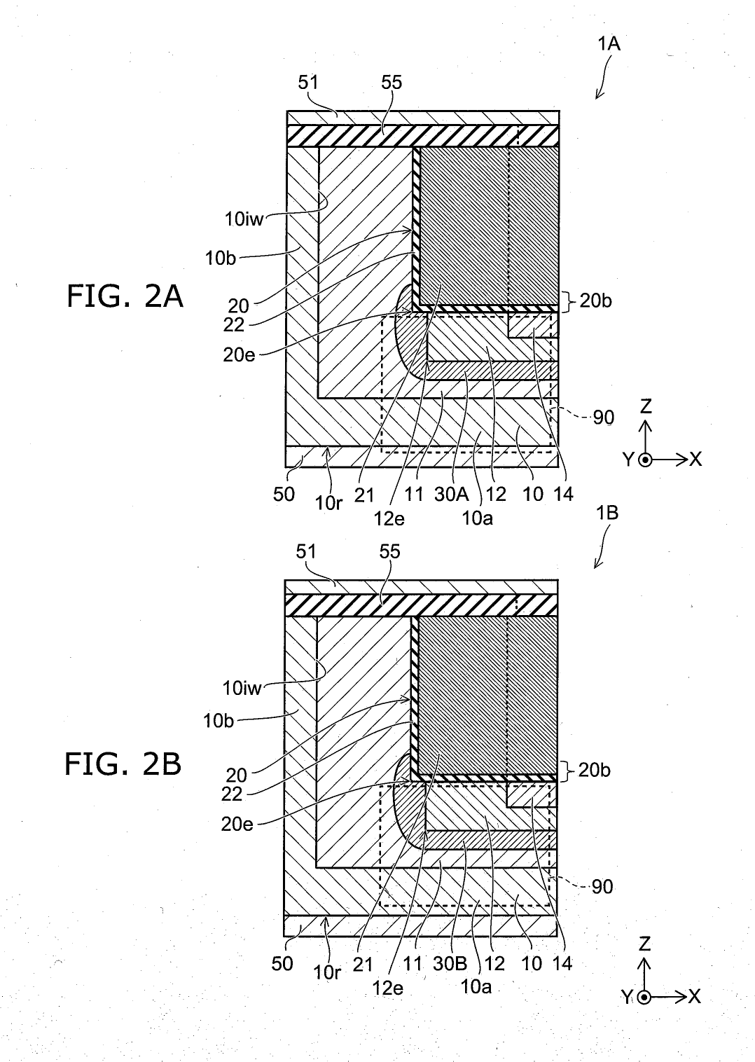

FIGS. 2A to 2B are schematic cross sectional views of the semiconductor device according to the first embodiment.

In both FIGS. 2A and 2B, a cross section at a position which is along a line A-B in FIG. 1 is shown. Further, in FIGS. 2A and 2B, a drain electrode 50 and a source electrode 51 which are not shown in FIG. 1 are shown.

A semiconductor device 1 according to the first embodiment is provided with a drain region 10 of a first conductivity type (n⁺-type), a source region 14 of the first conductivity type (n⁺-type), a base region 12 of a second conductivity type (p-type), a drift region 11 of the first conductivity type (n-type), a gate electrode 21, a gate insulating film 22, an electric field absorbing portion (a first semiconductor region) 30, a drain electrode 50 and a source electrode 51.

The drain region 10 has a first portion 10a and a second portion 10b which is extended in a first direction which is vertical to a main surface of the first portion 10a.

In this case, in the specification, it is assumed that the first direction is a Z-direction, a second direction corresponding to one of directions which are orthogonal to the first direction is a Y-direction, and a third direction which is orthogonal to the first direction and the second direction is an X-direction.

The source region 14 is provided in such a manner as to extend in the Z-direction and be away from the second portion 10b of the drain region 10 in the X-direction.

The drift region 11 is provided between the drain region 10 and the source region 14.

The base region 12 is provided between the source region 14 and the drift region 11.

The gate electrode 21 extends in the Z-direction and the X-direction, and passes through the base region 12 in the X-direction. In the embodiment, the gate electrode 12 is provided in such a manner as to pass through the source region 14 and the base region 12 in the X-direction.

The gate insulating film 22 is provided between the gate electrode 21 and at least the base region 12. In the embodiment, the gate insulating film 22 is provided in such a manner as to surround a periphery of the gate electrode 1 as seen in the Z-direction.

The electric field absorbing portion 30 is provided between the gate insulating film 22 and the drain region 10. The electric field absorbing portion 30 plays a part of absorbing the electric field of an end portion of the gate electrode 21 and an end portion of the base region 12.

The drain electrode 50 is connected to the drain region 10, and the source electrode 51 is connected to the source region 14 and the base region 12.

The semiconductor device 1 according to the first embodiment mentioned above is the MOSFET of the three-dimensional configuration. More specifically, the first portion 10a of the drain region 10 is a substrate of the semiconductor device 1 which is parallel to an X-Y plane. The second portion 10b of the drain region 10 has a surface which is parallel to a Y-Z plane. The drain region 10 has a first portion 10a, and a pair of second portions 10b which rise in the Z-direction from a main surface of the first portion 10a. In other words, a cross section of a Z-X plane of the drain region 10 is formed approximately as a U-shaped form.

In the semiconductor device 1, the drift region 11 of the first conductivity type (n-type) is provided in an inner side of the approximately U-shaped drain region 10 as an approximately U-shaped form in such a manner as to cover a surface of the drain region 10. The drift region 11 has a specific resistance which is higher than a specific resistance of the drain region 10. The base region 12 of the second conductivity type (p-type) is provided in an inner side of the approximately U-shaped drift region 11 as an approximately U-shaped form in such a manner as to cover the surface of the drift region 11. The source region 14 of the first conductivity type (n⁺-type) is provided in an inner portion of the approximately U-shaped base region 12 in such a manner as to pin in an inner side of the approximately U-shaped form of the base region 12.

In the semiconductor device 1, the trench 20 (the first trench) is provided to a depth which runs into the middle of the source region 14 in the Z-direction. In this case, the trench 20 may be provided to a depth in the middle of the base region 12 or in the middle of the drift region 11. The trench 20 is provided at a length which passes in the X-direction from a part of the source region 14 through the base region 12 which is adjacent to the part of the source region 14 and runs into a part of the drift region 11. The gate electrode (the trench gate electrode) 21 is provided within the trench 20 via the gate insulating film 22. In the example shown in FIG. 1, one gate electrode 21 is provided in the X-direction around the base region 12. In this case, two gate electrodes 21 may be arranged side by side in the X-direction around the base region 12.

In the semiconductor device 1, the electric field absorbing portion 30 is provided downward from the lower portion 20b of the trench 20. A specific resistance of the electric field absorbing portion 30 is higher than the specific resistance of the drain region 10 and the specific resistance of the drift region 11. A lower end portion 20e of the trench 20 (an end portion of the gate insulating film 22) and a lower end portion 12e of the base region 12 are covered by the electric field absorbing portion 30.

A main component of the drain region 10, the drift region 11, the base region 12, the source region 14 and the electric field absorbing portion 30 is, for example, a silicon (Si). A material of the gate electrode 21 is, for example, a polysilicon. A material of the gate insulating film 22 is, for example, a silicon oxide (SiO₂).

A semiconductor layer (or a semiconductor region) of “first conductivity type (n-type)” is a semiconductor in which an arsenic (As), a phosphorous (P) or the like is doped as an impurity element. A semiconductor of “second conductivity type (p-type)” is a semiconductor in which a boron (B) or the like is doped as an impurity element.

In an example shown in FIG. 1 and FIGS. 2A to 2B, a lower end of the trench 20 exists in an upper side than a lower end of the base region 12, however, the first embodiment includes a mode that the lower end of the trench 20 exists in a lower side than the lower end of the base region 12. The mode mentioned above is presented by the other drawings.

In an electric field absorbing region 30A of a semiconductor device 1A shown in FIG. 2A and a semiconductor device 1B shown in FIG. 2B, a composition of the electric field absorbing portion 30 (the electric field absorbing portion 30A or 30B) is different.

The electric field absorbing portion 30A shown in FIG. 2A is formed by implanting an impurity element of the second conductivity type to the drift region 11. For example, the impurity element of the second conductivity type is implanted to the drift region 11 from the trench 20 or the like, a heating treatment is further carried out, and the electric field absorbing portion 30A of the first conductivity type (n⁻-type) is formed downward from the lower portion 20b of the trench 20. In this ion implantation, the impurity element is implanted in such a degree that the conductivity type of the region of the implanted drift region 11 is not inverted. As a result, it is possible to form the electric field absorbing portion 30A of the first conductivity type (n⁻-type) in which the specific resistance is higher than the drift region 11.

The electric field absorbing portion 30B shown in FIG. 2B is formed by implanting the impurity element of the second conductivity type to the drift region 11. For example, the impurity element of the Second conductivity type is implanted to the drift region 11 from the trench 20 or the like, a heating treatment is further carried out, and the electric field absorbing portion 30B of the second conductivity type (p⁻-type) is formed downward from the lower portion 20b of the trench 20. The electric field absorbing portion 30B includes the impurity element of the first conductivity type and the impurity element of the second conductivity type. In this ion implantation, the impurity element is implanted in such a degree that the conductivity type of the region of the implanted drift region 11 is inverted. As a result, it is possible to form the electric field absorbing portion 30B of the second conductivity type (p⁻-type) in which the specific resistance is higher than the drift region 11.

A concentration of the impurity element of the second conductivity type in the electric field absorbing portion 30B is higher than a concentration of the impurity element of the first conductivity type in the electric field absorbing portion 30B. A value obtained by subtracting the concentration of the impurity element of the first conductivity type in the electric field absorbing portion 30B from the concentration of the impurity element of the second conductivity type in the electric field absorbing portion 30B is lower than the concentration of the impurity element of the second conductivity type which is included in the base region 12.

The drain electrode 50 is connected to the drain region 10. The source electrode 51 is provided on an interlayer insulating film 55. A part of the interlayer insulating film 55 is opened, and the source electrode 51 is connected to the source region 14 and the base region 12.

According to the semiconductor device 1 (the semiconductor devices 1A and 1B), the lower end portion 20e of the trench 20 and the lower end portion 12e of the base region 12 are covered by the electric field absorbing portion 30. Further, the electric field absorbing portion 30 is provided on the boundary of the base region 12 and the drift region 11 in the vicinity of a bottom portion of the trench 20.

On the basis of an on/off motion of the semiconductor device 1, a high electric voltage is applied between the drain electrode 50 and the source electrode 51. In the case that the electric field absorbing portion 30 is not provided, the electric field tends to be concentrated to the lower end portion 20e of the trench 20 and the lower end portion 12e of the base region 12. In other words, in the case that the electric field absorbing portion 30 is not provided, for example, a breakdown tends to be generated in the lower end portion 20e of the trench 20 and the lower end portion 12e of the base region 12.

In the first embodiment, the electric field absorbing portion 30 is provided, thereby absorbing the electric field concentration. Further, in the electric field absorbing portion 30, the specific resistance is higher than the drift region 11. Accordingly, at a time of the off motion, a depletion layer tends to be extended from the boundary between the base region 12 and the drift region 11. In other words, at a time of the off time, an electric field gradient or an electric field intensity in the vicinity of an interface of a pn junction is absorbed. As a result, the breakdown voltage of the semiconductor device 1 (the semiconductor devices 1A and 1B) becomes higher.

Further, according to the semiconductor device 1 (the semiconductor devices 1A and 1B), it is possible to further enhance the impurity concentration of the drift region 11 at a degree that the breakdown voltage becomes higher. As a result, in the semiconductor device 1 (the semiconductor devices 1A and 1B), a further lower on-resistance can be realized.

In the meantime, in the conventional vertical type MOSFET which is not the three-dimensional configuration, the electric field absorbing portion mentioned above can be provided in the vicinity of the lower end of the gate electrode. However, if the conventional vertical MOSFET is provided with the electric field absorbing portion mentioned above, an electric current route of the vertical MOSFET and the electric field absorbing portion are approximately overlapped. As mentioned above, the specific resistance of the electric field absorbing portion is lower than the drift region 11. Therefore, in the vertical type MOSFET in which the electric current route is provided with the electric field absorbing portion mentioned above, an increase of the on-resistance is caused.

On the contrary, in the semiconductor device 1 of the three-dimensional type configuration, a major part of an electron current flowing at a time of the on time flows approximately in parallel to a back surface 10r of the drain region 10. This is because an inverse layer (a channel) is formed in the base region 12 which is opposed to the gate electrode 21 via the gate insulating film 22, and the source region 14 and an inner side wall 10iw of the drain region 10 are opposed to each other with respect to the channel. In other words, a major part of the electron current flowing through the channel runs into the inner side wall 10iw of the drain region 10 as it is from the source region 14. In the semiconductor device 1, since the electric field absorbing portion 30 is provided downward from the lower end portion 20e of the trench 20, the electric current route is not blocked by the electric field absorbing portion 30. As a result, in the semiconductor device 1, an increase of the on-resistance is suppressed and the breakdown voltage becomes higher.

In the semiconductor device 1 of the three-dimensional type configuration, a region 90 between the bottom portion of the trench 20 and the drain region 10 comes to a region in which the electric current route is hard to be formed. By enhancing the breakdown voltage of the region 90 mentioned above, the increase of the on-resistance is held down, and the breakdown voltage is enhanced, in the semiconductor device 1.

### Second Embodiment

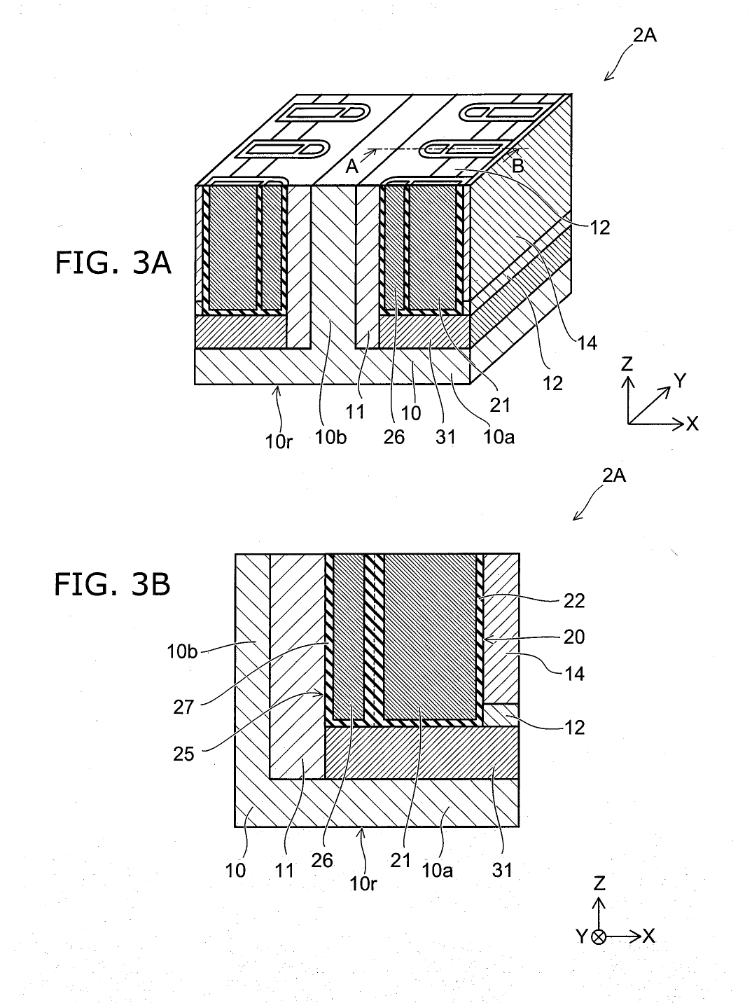

FIGS. 3A to 3B are schematic views of a semiconductor device according to a second embodiment.

FIG. 3A shows a schematic perspective view of the semiconductor device according to the second embodiment, and FIG. 3B shows a schematic cross sectional view at a position along a line A-B in FIG. 3A.

In a semiconductor device 2A according to the second embodiment, a trench 25 (the second trench) is provided further in the Z-direction. The trench 25 is provided between the trench 20 and the second portion 10b. The trench 25 comes into contact with the trench 20. In other words, the trench 25 is communicated with the trench 20. A field plate electrode 26 (a second field plate electrode) is provided within the trench 25 via a field plate insulating film 27 (a second field plate insulating film). In other words, a field plate configuration portion including the field plate electrode 26 and the field plate insulating film 27 is provided between the gate electrode 21 and the second portion 10b.

A material of the field plate electrode 26 is, for example, a polysilicon. A material of the field plate insulating film 27 is, for example, a silicon oxide (SiO₂). The trench 25 may be continuous with the trench 20 or be discontinuous. FIGS. 3A and 3B show a state in which the trench 25 is continuous with the trench 20. The field plate electrode 26 is electrically connected to the source electrode 51 (refer to FIG. 1) or the gate electrode 21 (refer to FIG. 1).

In the semiconductor device 2A, an electric field absorbing portion 31 is provided downward from a bottom surface of the trench 20 and a bottom surface of the trench 25. A composition of the electric field absorbing portion 31 is the same as a composition of the electric field absorbing portion 30. FIGS. 3A and 3B show a state in which the electric field absorbing portion 31 comes into contact with the drain region 10. A configuration in which the electric field absorbing portion 31 and the drain region 10 are not in contact is included in the second embodiment.

A specific resistance of the electric field absorbing portion 31 is higher than a specific resistance of the drain region 10 and a specific resistance of the drift region 11. The lower end portion 20e of the trench 20 and the lower end portion 12e of the base region 12 are covered by the electric field absorbing portion 31. Accordingly, the semiconductor device 2A presents the same operations and effects as the semiconductor device 1.

Further, in the semiconductor device 2A, since the field plate electrode 26 is provided within the drift region 11, the depletion layer formed in the drift region 11 tends to extend in comparison with the semiconductor device 1. As a result, in the semiconductor device 2A, the breakdown voltage is further enhanced in comparison with the semiconductor device 1. Further, in the semiconductor device 2A, since the drift region 11 tends to form the depletion, it is possible to enhance the impurity concentration of the drift region 11. As a result, in the semiconductor device 2A, the on-resistance is further lowered in comparison with the semiconductor device 1.

### Variation of Second Embodiment

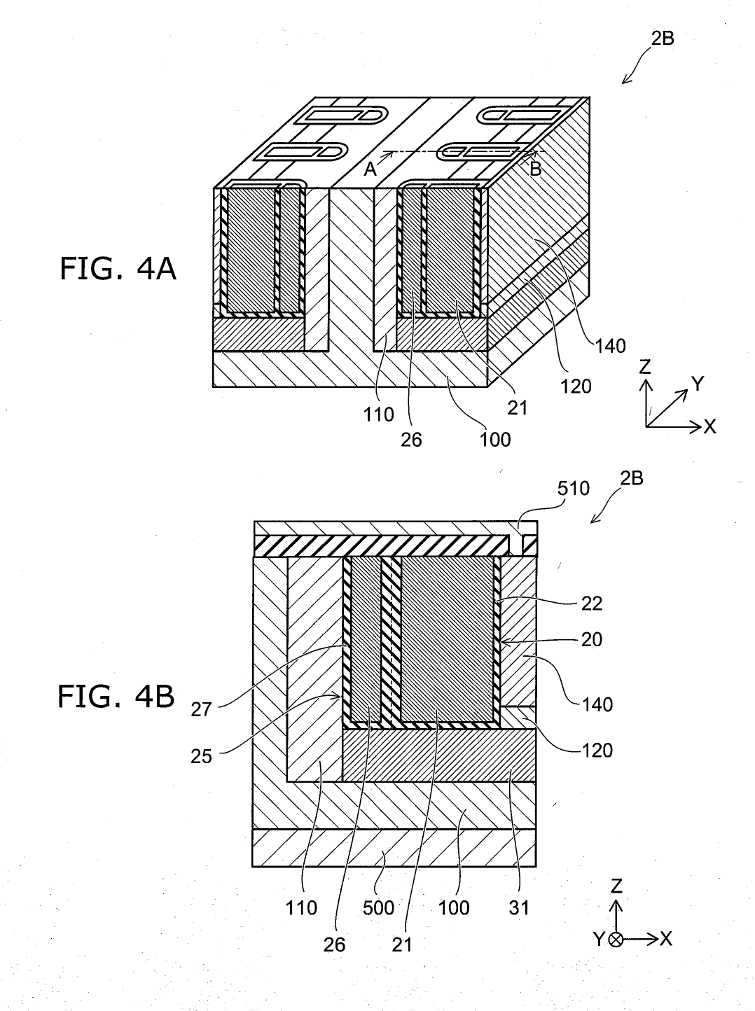

FIGS. 4A to 4B are schematic views of a semiconductor device according to a variation of the second embodiment.

FIG. 4A is a perspective schematic view, and FIG. 4B is a cross sectional schematic view.

FIG. 4B shows a cross section at a position along a line A-B in FIG. 4A. FIG. 4A does not show main electrodes 500 and 510 which are shown in FIG. 4B.

The semiconductor device 2B is obtained by converting the semiconductor device 2A into a three-dimensional type diode. For example, in the semiconductor device 2B, the base region 12 of the semiconductor device 2A is replaced by a charge storage layer 120 of the first conductivity type.

Comparing the configuration of the semiconductor device 2A with the configuration of the semiconductor device 2B, the first semiconductor layer 100 corresponds to the drain region 10. The second semiconductor layer 110 corresponds to the drift region 11. The third semiconductor layer 140 corresponds to the source region 14. The charge storage layer 120 corresponds to the base region 12. The first main electrode 500 corresponds to the drain electrode 50. The second main electrode 510 corresponds to the source electrode 51.

The first semiconductor layer 100 has a first portion 100a, and a second portion 100b which is vertical to the first portion 100a. A second semiconductor layer 110 of the first conductivity type which comes into contact with the second portion 100b is provided between the second portion 100b and the trench 25. A specific resistance of the second semiconductor layer 110 is higher than a specific resistance of the first semiconductor layer 100. The charge storage layer 120 which comes into contact with the trench 20 and has a low concentration is provided in an upper side of the electric field absorbing portion 31. A third semiconductor layer 140 of the first conductivity type which comes into contact with the trench 20 is provided on the charge storage layer 120.

The gate electrode 21 is provided via the gate insulating film 22 within the trench 20 which is provided in the Z-direction.

The electric field absorbing portion 31 is provided downward from the lower portion of the trench 20. The electric field absorbing portion 31 has a specific resistance which is higher than a specific resistance of the first semiconductor layer 100 and a specific resistance of the second semiconductor layer 110. The field plate electrode 26 is provided via the field plate insulating film 27 within the trench 25 which comes into contact with the trench 20 and is provided in the Z-direction.

The first main electrode 500 is connected to the first semiconductor layer 100. The second main electrode 510 is connected to the third semiconductor layer 140. The third semiconductor layer 140 and the second main electrode 510 form a Schottky junction. The field plate electrode 26 is electrically connected to the second main electrode 510 or the gate electrode 21.

On the assumption that the gate electrode 21 and the second main electrode 510 are set to an anode electrode, and the first main electrode 500 is set to a cathode electrode, the semiconductor device 2B can be assumed as a Schottky barrier diode of a gate control type.

In the semiconductor device 2B, if a positive electric potential is applied to the anode electrode (the gate electrode 21 and the second main electrode 510), and a negative electric potential is applied to the cathode electrode (the first main electrode 500) (a forward bias), the electron is induced from the charge storage layer 120 in the vicinity of the gate insulating film 22, a channel is formed in the charge storage layer 120 in the vicinity of the gate insulating film 22, and an electric current flows between the anode electrode and the cathode electrode.

On the other hand, in the semiconductor device 2B, if the negative electric potential is applied to the anode electrode, and the positive electric potential is applied to the cathode electrode (a backward bias), the electron is cleared away from the charge storage layer 120 in the vicinity of the gate insulating film 22, and the channel is not formed in the charge storage layer 120 in the vicinity of the gate insulating film 22. In other words, the electric current does not flow between the anode electrode and the cathode electrode. Accordingly, the semiconductor device 2B shows a good rectifying action.

Further, since the semiconductor device 2B is provided with the field plate electrode 26, it is possible to set the impurity concentration included in the second semiconductor layer 110 high. As a result, the specific resistance of the second semiconductor layer 110 becomes low, and an electric voltage (a forward voltage drop (VF)) which is necessary for circulating the electric current in the forward direction of the diode becomes low.

### Third Embodiment

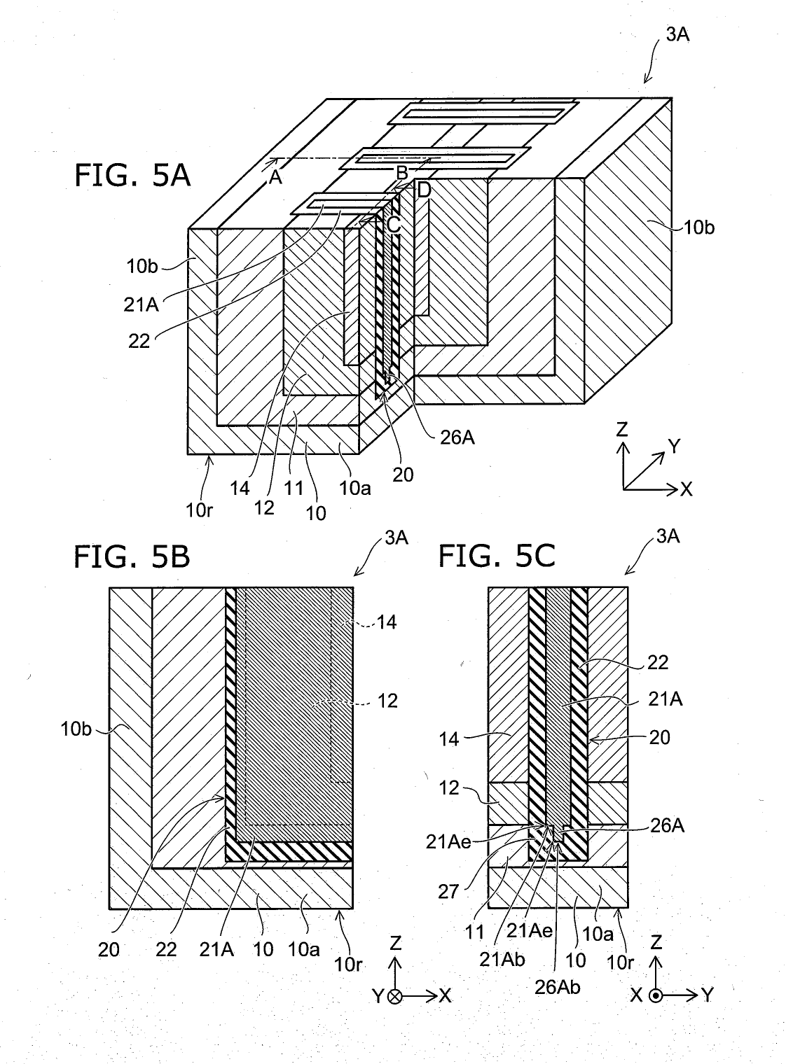

FIGS. 5A to 5C are schematic views illustrating a semiconductor device according to a third embodiment.

FIG. 5A shows a schematic perspective view in which a part of the semiconductor device according to the third embodiment is broken. FIG. 5B shows a cross section at a position along a line A-B in FIG. 5A. FIG. 5C shows a cross section at a position along a line C-D in FIG. 5A. In this case, the drain electrode 50 and the source electrode 51 mentioned above are not shown in FIGS. 5A to 5C.

A semiconductor device 3A according to the third embodiment is configured such that a drift region 11 having a higher specific resistance than a specific resistance of a drain region 10 is provided in an inner side of the approximately U-shaped drain region 10 as an approximately U-shaped form in such a manner as to cover the surface of the drain region 10. A base region 12 is provided in the inner side of the approximately U-shaped drift region 11 as an approximately U-shaped form in such a manner as to cover the surface of the drift region 11. A source region 14 is provided in the inner portion of the approximately U-shaped base region 12 in such a manner as to pin in the inner side of the approximately U-shaped form of the base region 12. The drain region 10 has a first portion 10a, and a second portion 10b. The source region 14 is provided in such a manner as to extend in the Z-direction and be spaced from the drain region 10 in the X-direction. The drift region 11 is provided between the drain region 10 and the source region 14.

Further, in the semiconductor device 3A, a trench 20 is provided to a depth which reaches the middle of the drift region 11 in the Z-direction. The trench 20 is provided at a length which passes from a part of the source region 14 through the base region 12 which is adjacent to the part of the source region 14 in the X-direction so as to run into a part of the drift region 11. A gate electrode 21A and a field plate electrode 26A (a first field plate electrode) are provided within the trench 20. The gate electrode 21A is provided within the trench 20 via the gate insulating film 22.

The field plate electrode 26A is provided within the trench 20 via a field plate insulating film 27 (a first field plate insulating film). The field plate electrode 26A and the field plate insulating film 27 configure an electric field absorbing portion. A thickness (a thickness in the Y-direction) of the field plate insulating film 27 is thicker than a thickness (a thickness in the Y-direction) of the gate insulating film 22. The field plate electrode 26A is provided in a lower side of the gate electrode 21A. The field plate electrode 26A is connected to the gate electrode 21A. On the assumption that the field plate electrode 26A is a part of the gate electrode 21A, a part of the lower portion of the gate electrode 21A is functioned as a field plate electrode, in the semiconductor device 3A.

A distance between a back surface 10r of the drain region 10 and a lower end 26Ab of the field plate electrode 26A is shorter than a distance between the back surface 10r of the drain region 10 and a lower end 21Ab of the gate electrode 21A. A drain electrode 50 is connected to the drain region 10, and a source electrode 51 is connected to the source region 14 and the base region 12 (not illustrated).

In the case that the field plate electrode 26A is not provided, an electric field concentration tends to be generated in the lower end portion 21Ae of the gate electrode 21A, and a break down in the vicinity of a lower end portion 21Ae of the gate electrode 21A tends to be generated. On the contrary, in the semiconductor device 3A, the electric field concentration is generated in the lower end portion 26Ae of the field plate electrode 26A in addition to the lower end portion 21Ae of the gate electrode 21A. As a result, the electric field concentration is dispersed, and a breakdown voltage of the semiconductor device 3A becomes higher.

Further, in the semiconductor device 3A, the lower end of the trench 20 exists in a lower side than the lower end of the base region 12. In the semiconductor device 3A, a part of the drift region 11 is opposed to the field plate electrode 26A. As a result, a channel is formed in a bottom portion of the trench 20, and a channel width per a unit cell becomes wider. As a result, an on-resistance of the semiconductor device 3A is further reduced.

Further, in the semiconductor device 3A, the field plate electrode 26A is connected to the gate electrode 21A, and is arranged below the gate electrode 21A. As a result, a configuration of the field plate electrode 26A becomes simple.

### First to Third Variations of Third Embodiment

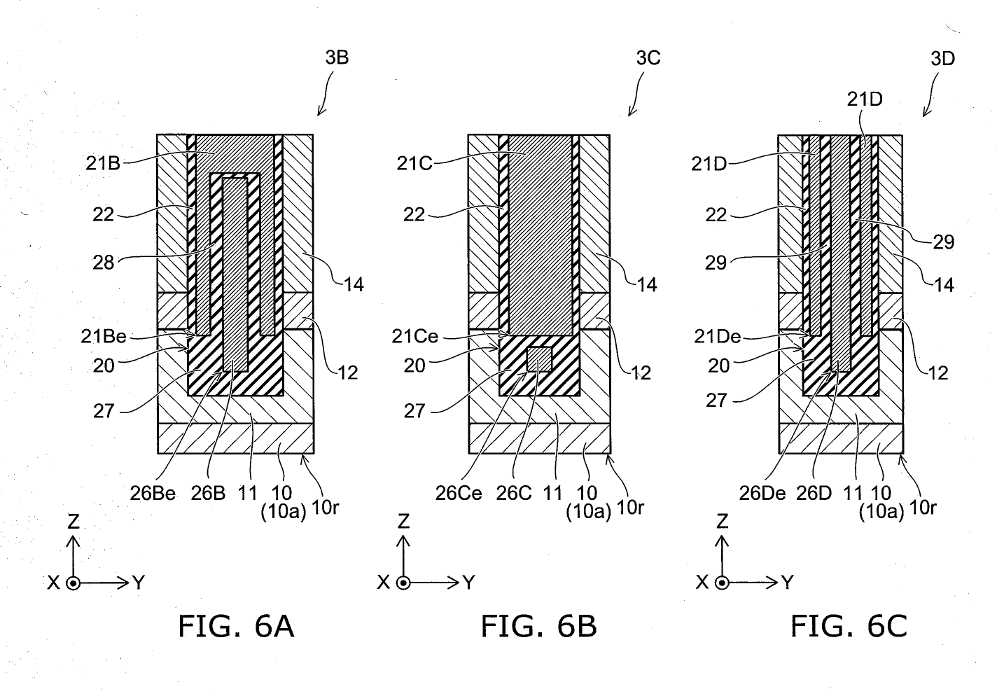

FIGS. 6A to 6C are schematic cross sectional views showing variations of the third embodiment.

FIG. 6A shows a first variation, FIG. 6B shows a second variation, and FIG. 6C shows a third variation. Each of FIGS. 6A to 6C corresponds to the direction shown in FIG. 5C.

FIG. 6A shows a semiconductor device 3B according to the first variation of the third embodiment.

In the semiconductor device 3B, an upper portion of a field plate electrode 26B is inserted to a lower portion of a gate electrode 21B via an insulating layer 28. In other words, as seen in the Y-direction, a part of the field plate electrode 26B laps over a part of the gate electrode 21B. In the semiconductor device 3B, a part of the field plate electrode 26B is surrounded by the gate electrode 21B via the insulating layer 28. An electric potential of the field plate electrode 26B is in a floating state. A lower end of the gate electrode 21B exists in a lower side than the lower end of the base region 12.

In the semiconductor device 3B, a part of the field plate electrode 26B is pinched by a part of the gate electrode 21B via the insulating layer 28. In the semiconductor device 3B, the field plate electrode 26B and the gate electrode 21B have an opposed area which is sufficient for a capacity coupling. As a result, even if the electric potential of the field plate electrode 26B is in a floating state, the electric potential of the field plate electrode 26B comes close to the electric potential of the gate electrode 21B.

In the case that the field plate electrode 26B is not provided, an electric field concentration tends to be generated in a lower end portion 21Be of the gate electrode 21B, and a breakdown tends to be generated in the vicinity of the lower end portion 21Be of the gate electrode 21B. On the contrary, in the semiconductor device 3B, the electric field concentration is generated in the lower end portion 26Be of the field plate electrode 26B in addition to the lower end portion 21Be of the gate electrode 21B. As a result, the electric field concentration is dispersed, and the breakdown voltage of the semiconductor device 3B becomes higher.

FIG. 6B shows a semiconductor device 3C according to the second variation of the third embodiment.

In the semiconductor device 3C, a field plate electrode 26C is provided in a lower side of a gate electrode 21C. In other words, the field plate electrode 26C is spaced from the gate electrode 21 in the Z-direction. A center axis of the field plate electrode 26C coincides with a center axis of the gate electrode 21C. The field plate electrode 26C is electrically connected to the source electrode 51 or the gate electrode 21C.

In the case that the field plate electrode 26C is not provided, the electric field concentration tends to be generated in a lower end portion 21Ce of the gate electrode 21C, and a breakdown tends to be generated in the vicinity of the lower end portion 21Ce of the gate electrode 21C. On the contrary, in the semiconductor device 3C, the electric field concentration is generated in the lower end portion 26Ce of the field plate electrode 26C in addition to the lower end portion 21Ce of the gate electrode 21C. As a result, the electric field concentration is dispersed, and the breakdown voltage of the semiconductor device 3C becomes higher.

FIG. 6C shows a semiconductor device 3D according to the third variation of the third embodiment.

In the semiconductor device 3D, a field plate electrode 26D is pinched by a gate electrode 21D via an insulating layer 29. The field plate electrode 26D is electrically connected to the source electrode 51 or the gate electrode 21D.

In the case that the field plate electrode 26D is not provided, the electric field concentration tends to be generated in a lower end portion 21De of the gate electrode 21D, and a breakdown tends to be generated in the vicinity of the lower end portion 21De of the gate electrode 21D. On the contrary, in the semiconductor device 3D, the electric field concentration is generated in a lower end portion 26De of the field plate electrode 26D, in addition to the lower end portion 21De of the gate electrode 21D. As a result, the electric field concentration is dispersed, and the breakdown voltage of the semiconductor device 3D becomes higher.

### Fourth Embodiment

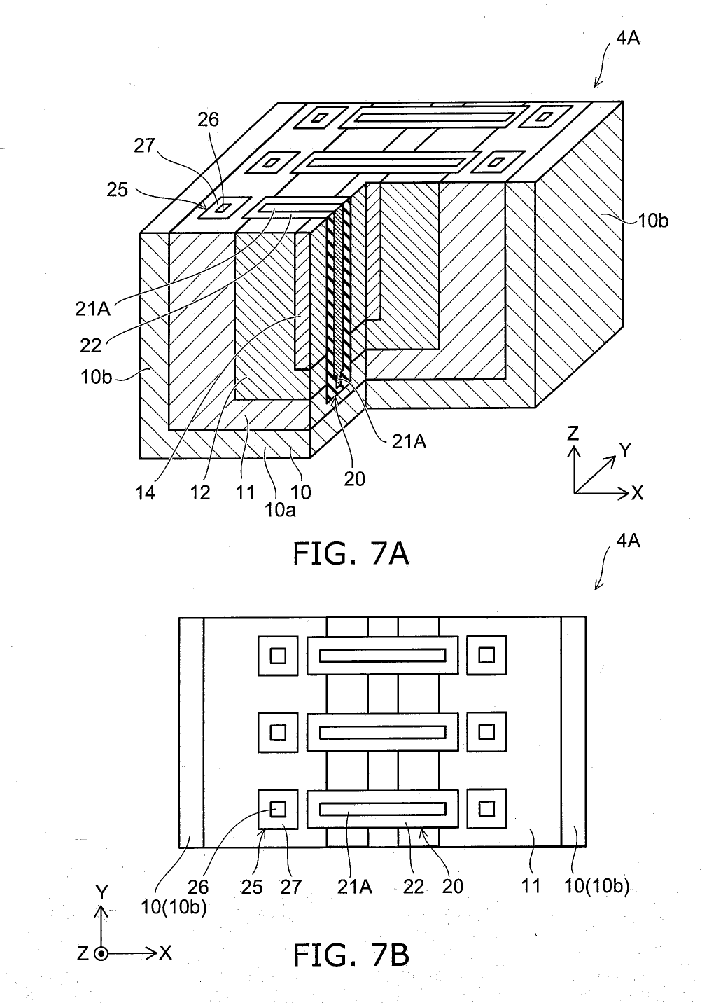

FIGS. 7A to 7B are schematic views illustrating a semiconductor device according to a fourth embodiment.

FIG. 7A shows a schematic perspective view in which a part of the semiconductor device according to the fourth embodiment is broken. FIG. 7B shows a schematic top elevational view of the semiconductor device according to the fourth embodiment.

A basic configuration of a semiconductor device 4A according to the fourth embodiment is the same as the semiconductor device 3A. In this case, the semiconductor device 4A is provided with a field plate electrode 26 via a field plate insulating film 27 within a trench 25 which is provided in the Z-direction The field plate electrode 26 and the field plate insulating film 27 configure an electric field absorbing portion. The field plate electrode 26 is electrically connected to a source electrode 51 (not illustrated in FIGS. 7A and 7B) or a gate electrode 21A.

In the semiconductor device 4A, since the field plate electrode 26 is provided within the drift region 11, the depletion layer formed in the drift region 11 tends to be extended in comparison with the semiconductor device 3A. As a result, in the semiconductor device 4A, the breakdown voltage is further enhanced in comparison with the semiconductor device 3A. Further, in the semiconductor device 4A, since the drift region 11 tends to be depleted, it is possible to enhance an impurity concentration of the drift region 11. As a result, in the semiconductor device 4A, the on-resistance is further lowered in comparison with the semiconductor device 3A.

If the field plate electrode 26 is connected to the source electrode 51, a capacity (Cgd) between the gate and the drain is reduced. As a result, a switching property of the semiconductor device 4A is improved.

### First to Third Variations of Fourth Embodiment

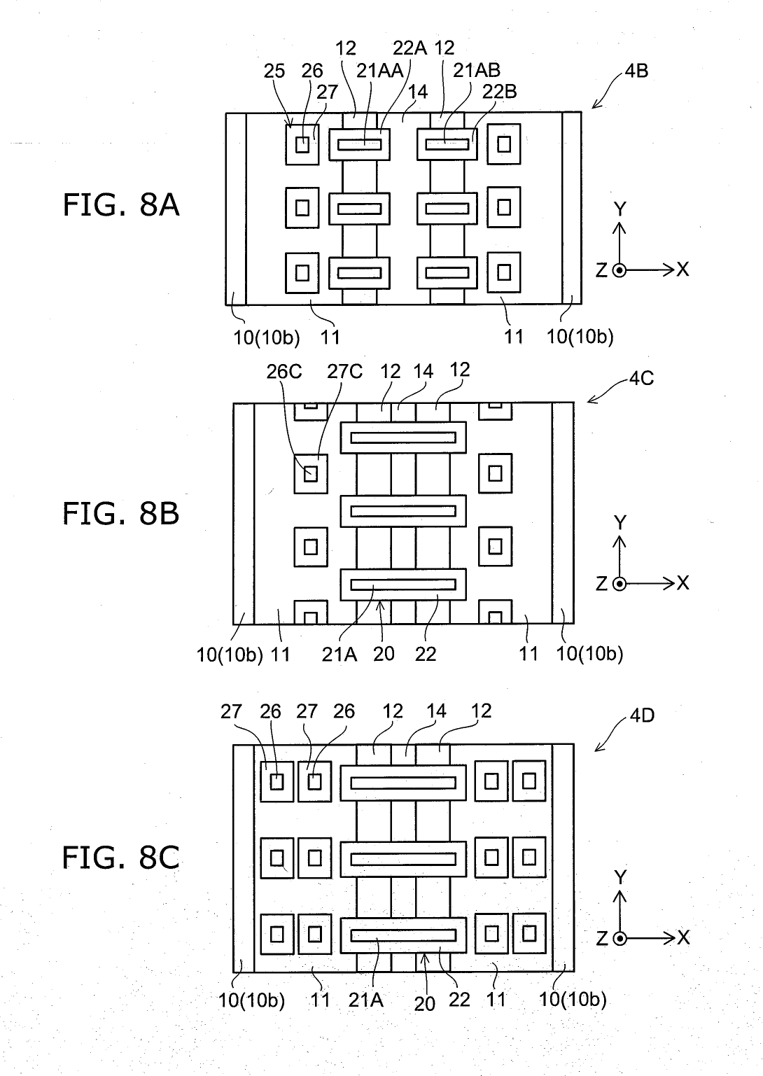

FIGS. 8A to 8C are schematic top elevational views showing variations of the fourth embodiment.

FIG. 8A shows a first variation, FIG. 8B shows a second variation, and FIG. 8C shows a third variation.

FIG. 8A shows a semiconductor device 4B according to a first variation of the fourth embodiment.

In FIG. 8A, a direction in which the gate electrode extends is set to an X-direction, and a direction which is vertical to the direction in which the gate electrode extends is set to a Y-direction. Same applies to FIGS. 8B and 8C.

The semiconductor device 4B has the same basic configuration as the semiconductor device 4A. In this case, in the semiconductor device 4B, the gate electrode extending in the X-direction does not pass through the source region 14. The semiconductor device 4B has such a configuration that the gage electrode 21A of the semiconductor device 4A is divided into two sections.

In other words, the semiconductor device 4B is provided with a gate electrode 21AA which extends in the X-direction, and a gate electrode 21AB. The gate electrode 21AA runs into a part of the drift region 11 from a part of the source region 14 while passing through the base region 12 which is adjacent to the part of the source region 14. The gate electrode 21AB runs into a part of the drift region 11 from a part of the source region 14 while passing through the base region 12 which is adjacent to the part of the source region 14. The mode mentioned above is included in the embodiment.

FIG. 8B shows a semiconductor device 4C according to a second variation of the fourth embodiment.

The semiconductor device 4C has the same basic configuration as the semiconductor device 4A. In this case, in the semiconductor device 4C, a field plate electrode 26C (a third field plate electrode) and a field plate insulating film 27C (a third field plate insulating film) are provided within the drift region 11 which is positioned between the gate electrodes 21 which are adjacent in the Y-direction.

In other words, the field plate electrode 26C is provided between the base region 12 and the second portion 10b of the drain region 10. Further, the field plate insulating film 27C is provided between the field plate electrode 26C and the drift region 11. The mode mentioned above is included in the embodiment.

FIG. 8C shows a semiconductor device 4D according to a third variation of the fourth embodiment.

The semiconductor device 4D has the same basic configuration as the semiconductor device 4A. In this case, in the semiconductor device 4D, a plurality of field plate electrodes 26 are arranged in the X-direction within the drift region 11. The mode mentioned above is included in the embodiment.

### Fifth Embodiment

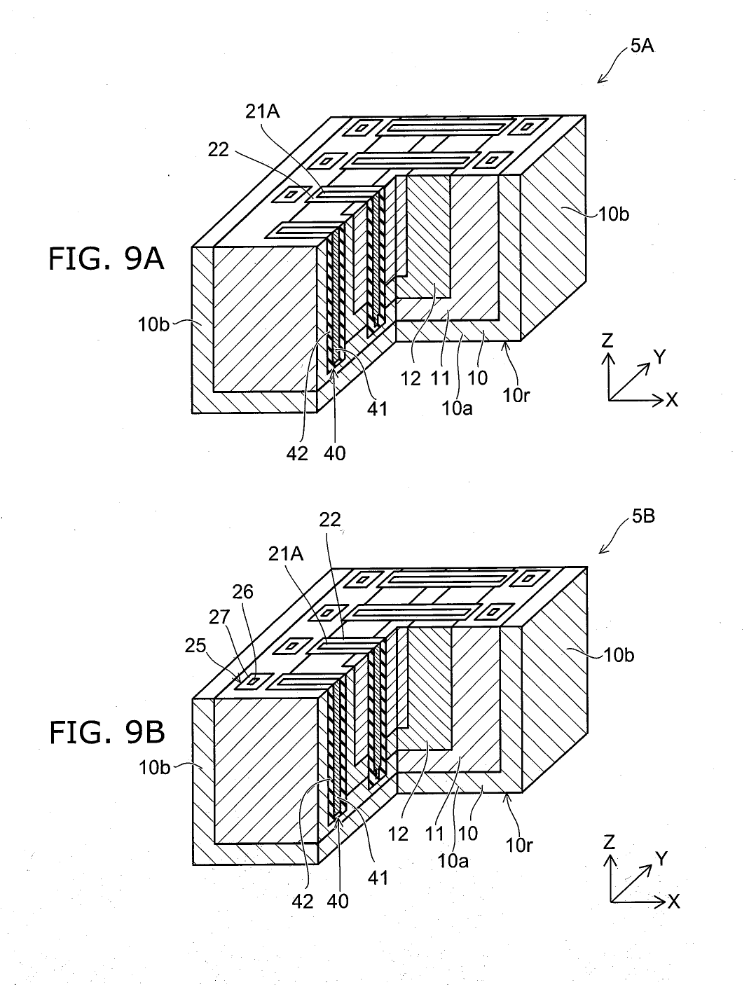

FIGS. 9A to 9B are schematic perspective views illustrating a semiconductor device according to a fifth embodiment.

FIG. 9A shows a schematic perspective view in which a part of a semiconductor device 5A according to the fifth embodiment is broken.

In the semiconductor device 5A, a gate electrode 21A extends in the X-direction. Further, in the semiconductor device 5A, a trench 40 (a third trench) is provided in a terminal end in the Y-direction of the base region 12. The trench 40 is provided at a depth in the middle of the drift region 11 in the Z-direction. Further, the trench 40 is provided at a length which passes through the base region 12 and the drift region 11 in the X-direction. A field plate electrode 41 is provided via a third field plate insulating film 42, within the trench 40. In other words, the field plate electrode 41 is provided at a terminal end of the base region 12.

A thickness (a thickness in the Y-direction) of the third field plate insulating film 42 is thicker than a thickness (a thickness in the Y-direction) of the gate insulating film 22. The field plate electrode 41 may be connected to the source electrode 51 (not illustrated in FIGS. 9A and 9B) or the gate electrode 21A.

A pn junction is formed in a portion in which the base region 12 terminates. As a result, there is a case that a gradient of an electric voltage in the vicinity of the pn junction becomes sharp. In the semiconductor device 5A, the field plate electrode 41 is arranged in a pn junction interface of the portion in which the base region 12 terminates. As a result, the gradient of the electric voltage in this portion is absorbed. As a result, the breakdown voltage of the semiconductor device 5A becomes further higher.

FIG. 9B shows a schematic perspective view in which a part of another semiconductor device 5B according to the fifth embodiment is broken.

A basic configuration of the semiconductor device 5B is the same as the semiconductor device 5A. In this case, the semiconductor device 5B is further provided with the trench 25. The trench 25 is provided in the Z-direction between the trench 40 and the second portion 10b. Within the trench 25, the field plate electrode 26 is provided via the field plate insulating film 27. The field plate electrode 26 is electrically connected to the source electrode 51 (not illustrated in FIGS. 7A and 7B) or the gate electrode 21A.

In the semiconductor device 5B, since the field plate electrode 26 is provided within the drift region 11, the depletion layer formed in the drift region 11 tends to extend in comparison with the semiconductor device 5A. As a result, in the semiconductor device 5B, the breakdown voltage is further enhanced in comparison with the semiconductor device 5A. Further, in the semiconductor device 5B, since the drift region 11 tends to be depleted, it is possible to enhance the impurity concentration of the drift region 11. As a result, in the semiconductor device 5B, the on-resistance is further lowered in comparison with the semiconductor device 5A.

### Sixth Embodiment

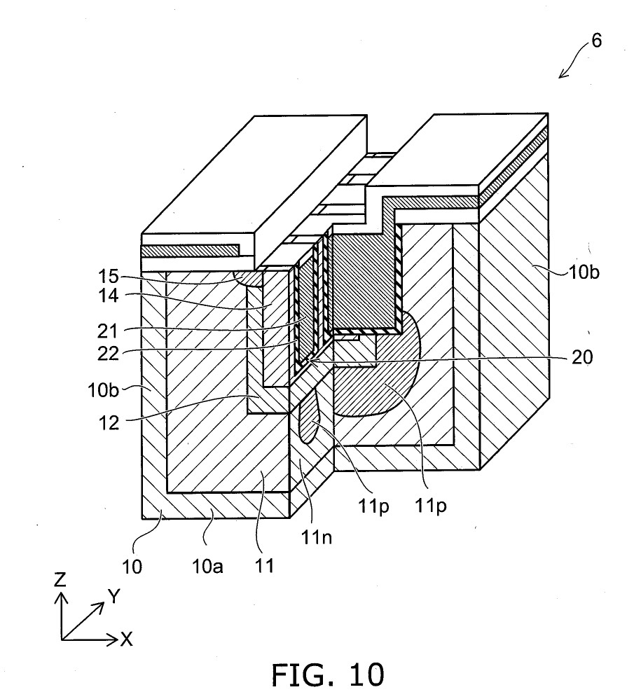

FIG. 10 is a schematic perspective view illustrating a semiconductor device according to a sixth embodiment.

FIG. 10 shows a schematic perspective view in which a part of a semiconductor device 6 according to the sixth embodiment is broken.

As shown in FIG. 10, a super junction configuration is provided within the drift region 11, in the semiconductor device 6 according to the sixth embodiment.

In the semiconductor device 6, the trench 20 provided with the gate electrode 21 is provided within the source region 14. A depth of the trench 20 is shallower than a depth of the source region 14. The gate electrode 21 is provided within the trench 20 via the gate insulating film 22.

A p⁻ region 11p is periodically provided in the Y-direction, in the drift region 11 in the lower side of the gate electrode 21. A pitch in the Y-direction of the p⁻ region 11p is the same as a pitch in the Y-direction of the gate electrode 21.

As a result, the drift region 11 is provided with an n⁻ region 11n and the p⁻ region 11p alternately. In other words, a charge balance of the drift region 11 becomes equal and the super junction configuration is configured.

In the semiconductor device 6 having the super junction configuration mentioned above, a low on-resistance and a high breakdown voltage are achieved.

### Seventh Embodiment

Next, a description will be given of a manufacturing method (first one) of a semiconductor device according to an embodiment.

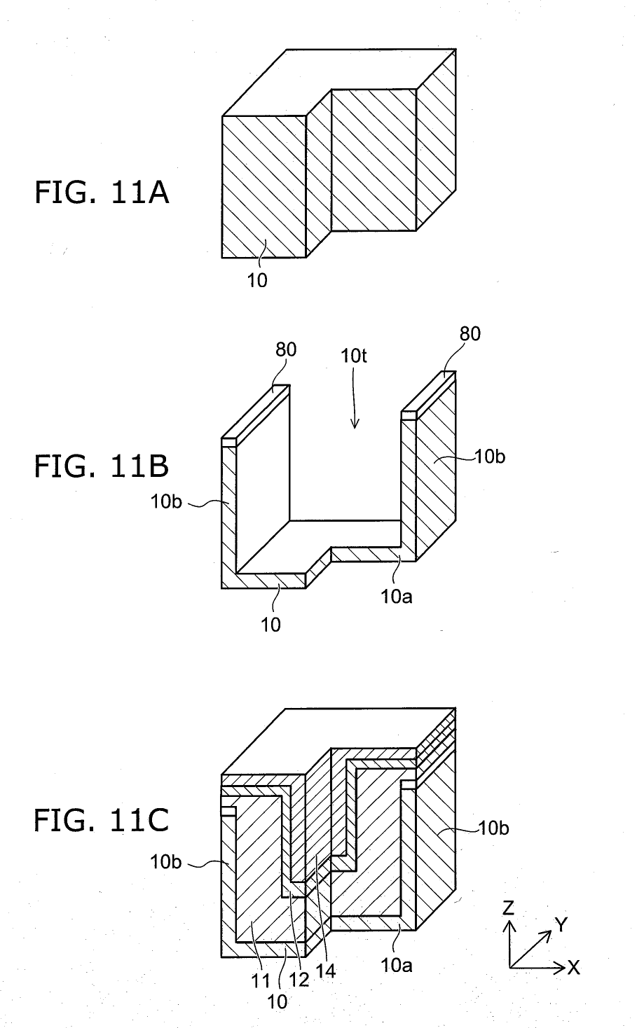

FIG. 11A to FIG. 14B are schematic perspective views illustrating the manufacturing method (first one) of the semiconductor device.

In FIG. 11A to FIG. 14B, each of processes of the manufacturing method of the semiconductor device 1 (refer to FIG. 1) is shown by a schematic perspective view which is partly broken.

First of all, as shown in FIG. 11A, a semiconductor substrate such as an n⁺-type silicon or the like is prepared. The semiconductor substrate comes to the drain region 10. Next, as shown in FIG. 11B, a mask material 80 such as a silicon oxide or the like is formed, and a trench 10t is formed in a portion in which the mask material 80 is not provided. The semiconductor substrate at a position of the trench 10t comes to the first portion 10a of the drain region 10, and the semiconductor substrate at a position of the mask material 80 comes to the second portion 10b of the drain region 10.

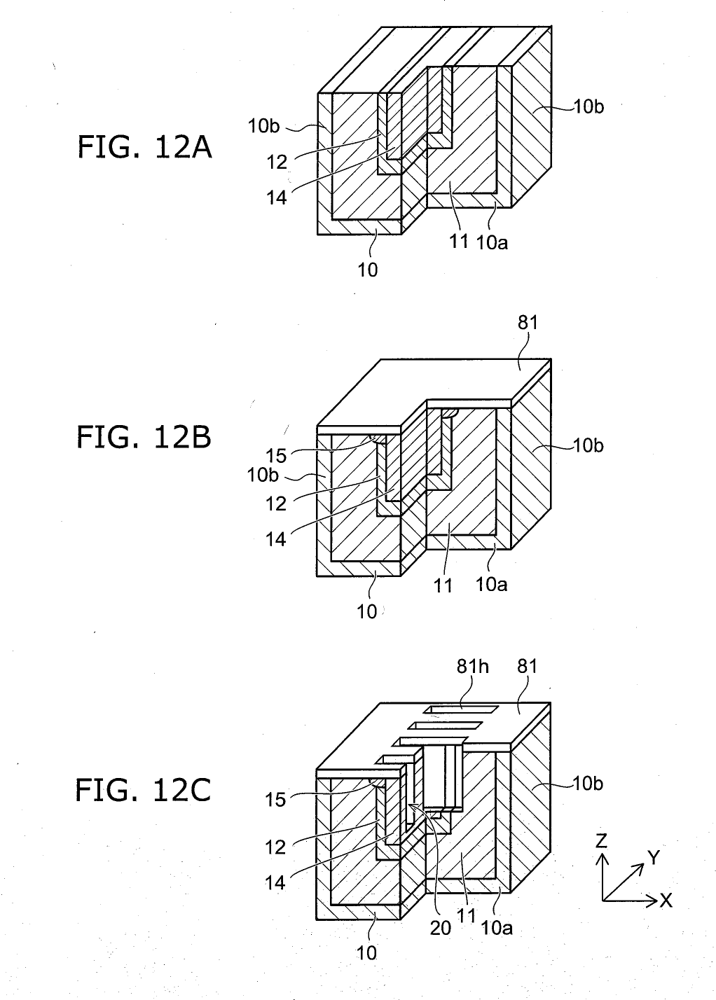

Next, as shown in FIG. 11C, the n⁻-type drift region 11, the p⁻-type base region 12 and the n⁺-type source region 14 are epitaxial grown in this order within the trench 10t. Next, as shown in FIG. 12A, each of the epitaxial grown regions is ground by a chemical mechanical polishing (CMP) or the like, and is flattened along the X-Y plane.

Next, as shown in FIG. 12B, a p⁺-type contact region 15 is formed in an upper portion of the base region 12, and a silicon oxide film 81 is thereafter formed on an upper surface. Next, as shown in FIG. 12C, an opening 81h is formed in the silicon oxide film 81, and the trench 20 is formed via the opening 81h. The trench 20 is formed to the middle of the source region 14. In this case, the trench 20 may be formed to the middle of the base region 12 and to the middle of the drift region 11.

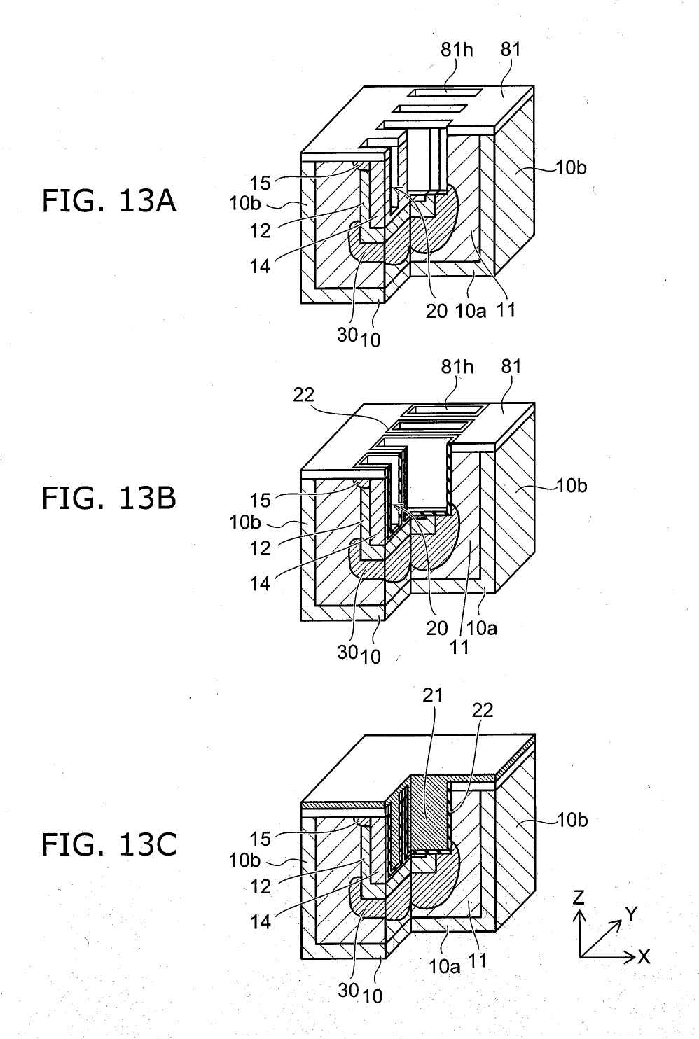

Next, as shown in FIG. 13A, a p-type dopant (for example, a boron) is ion implanted from an opening of the trench 20 toward a bottom portion. As a result, the electric field absorbing portion 30 is formed between the base region 12 and the drift region 11. The electric field absorbing portion 30 is, for example, the n⁻⁻ region which is formed by ion implanting the p-type dopant into the n⁻-type drift region 11.

Next, as shown in FIG. 13B, the gate insulating film 22 made of the silicon oxide or the like is formed in an inner wall of the trench 20. Next, as shown in FIG. 13C, the gate electrode 22 such as the polysilicon or the like is formed within the trench 20 via the gate insulating film 22.

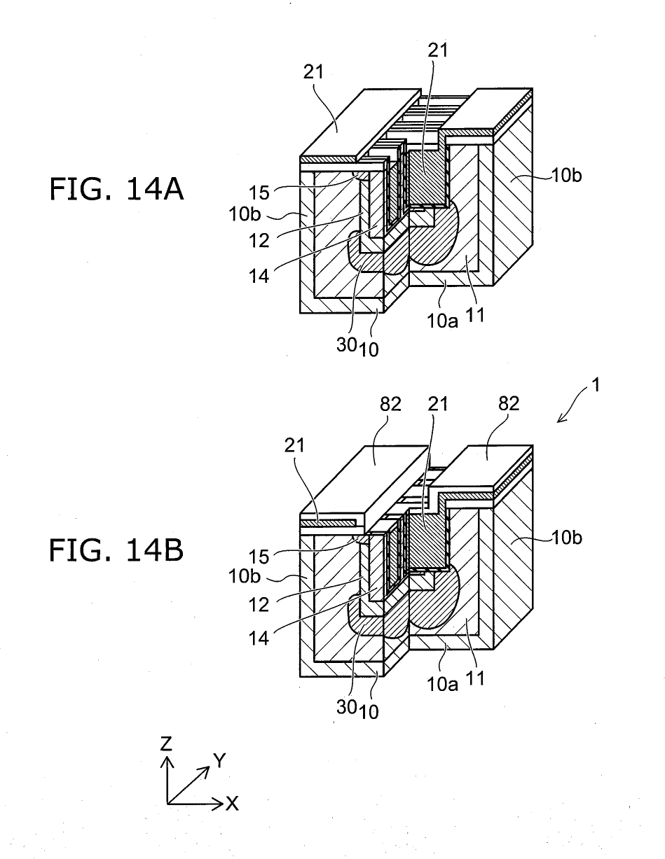

Next, as shown in FIG. 14A, the polysilicon or the like which is the material of the gate electrode 21 is etched back. The gate electrode 21 between the silicon oxide films 81 is exposed by the etch back. Next, as shown in FIG. 14B, after the insulating film 82 is formed on the gate electrode 21, the contact of the source region 12 is formed.

Thereafter, the source electrode (not illustrated) connected to the source region 12 and the drain electrode (not illustrated) connected to the drain region 10 are formed. As a result, the semiconductor device 1 is completed.

### Eighth Embodiment

Next, a description will be given of a manufacturing method (second one) of a semiconductor device according to an embodiment.

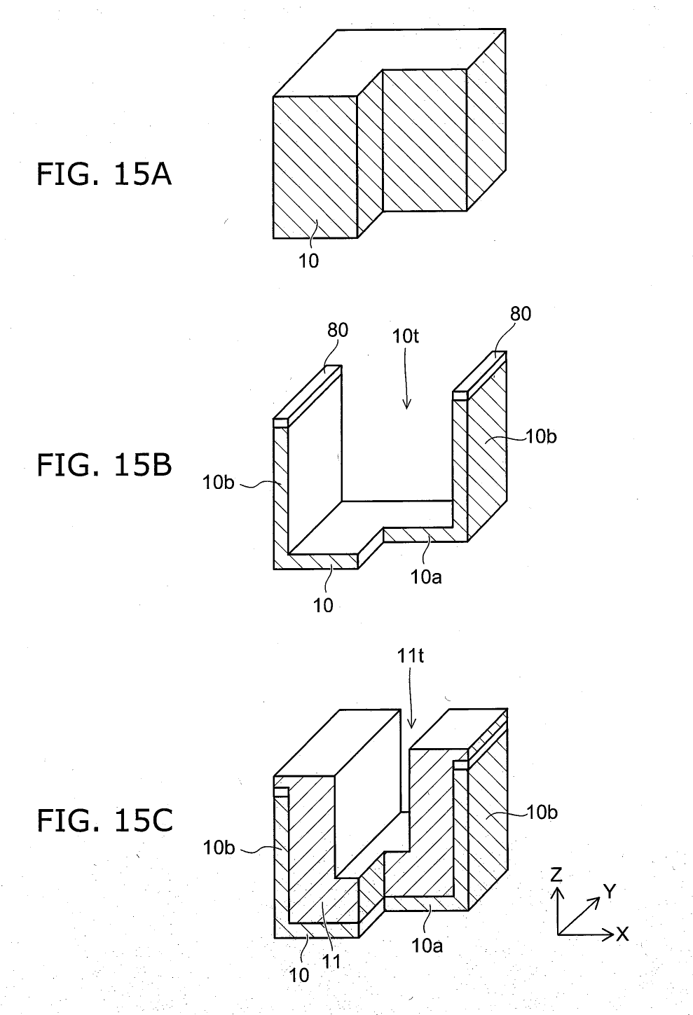

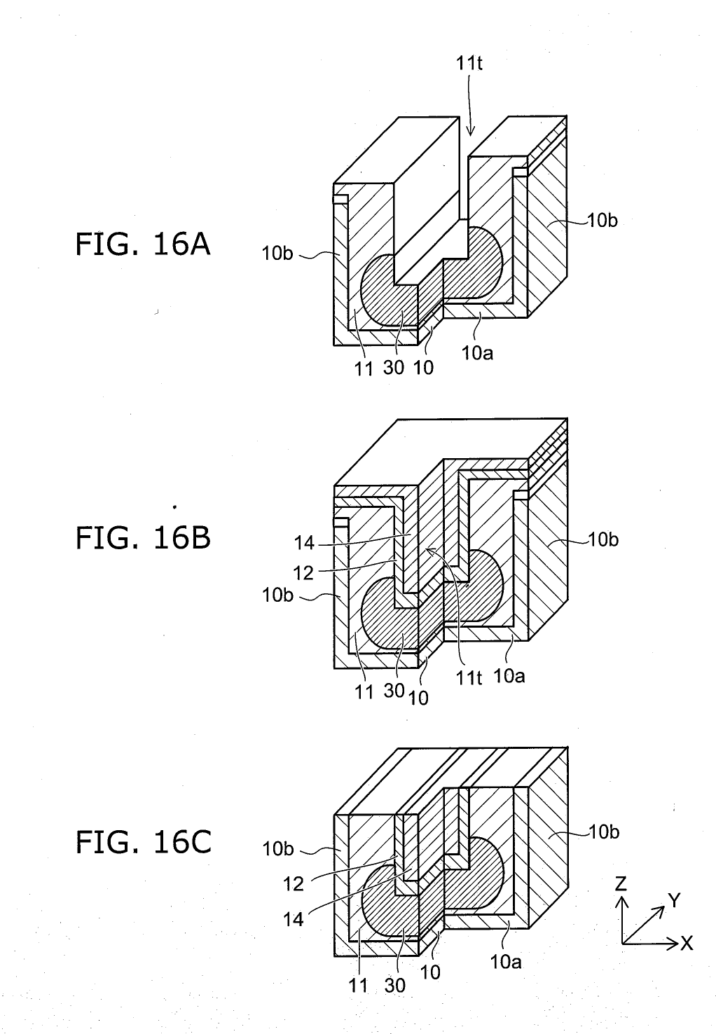

FIGS. 15A to 16C are schematic perspective views illustrating the manufacturing method (second one) of the semiconductor device. In FIG. 15A to FIG. 16C, each of processes in another embodiment of the manufacturing method of the semiconductor device 1 (refer to FIG. 1) is shown by a schematic perspective view which is partly broken.

First of all, as shown in FIG. 15A, a semiconductor substrate such as an n⁺-type silicon or the like is prepared. The semiconductor substrate comes to the drain region 10. Next, as shown in FIG. 15B, the mask material 80 such as a silicon oxide or the like is formed, and the trench 10t is formed in a portion in which the mask material 80 is not provided. The semiconductor substrate at the position of the trench 10t comes to the first portion 10a of the drain region 10, and the semiconductor substrate at the position of the mask material 80 comes to the second portion 10b of the drain region 10.

Next, as shown in FIG. 15C, after the n⁻-type drift region 11 is epitaxial grown within the trench 10t, a trench 11t is formed. The trench 11t is formed from the upper surface of the drift region 11 to the middle of the inner portion.

Next, as shown in FIG. 16A, a p-type dopant (for example, the boron) is ion implanted from an opening of the trench 11t toward a bottom portion. As a result, the electric field absorbing portion 30 is formed in a bottom portion side of the trench 11t in the drift region 11. The electric field absorbing portion 30 is, for example, the n⁻⁻ region which is formed by ion implanting the p-type dopant into the n⁻-type drift region 11.

Next, as shown in FIG. 16B, the p⁻-type base region 12 and the n⁺-type source region 14 are epitaxial grown in this order within the trench 11t. Next, as shown in FIG. 16C, each of the epitaxial grown regions is ground by the CMP or the like, and is flattened along the X-Y plane.

After the flattening, the same processes as the manufacturing process (first one) of the semiconductor device shown in FIGS. 12B to 14B are carried out. As a result, the semiconductor device 1 is completed.

### Ninth Embodiment

Next, a description will be given of a manufacturing method (third one) of a semiconductor device according to an embodiment.

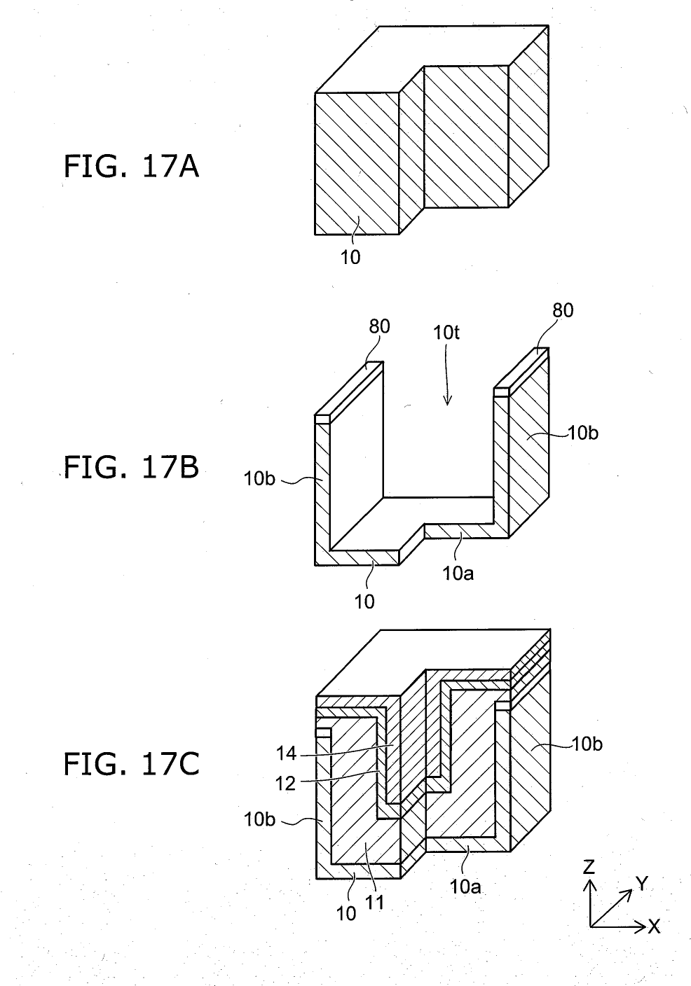

FIGS. 17A to 21B are schematic perspective views illustrating the manufacturing method (third one) of the semiconductor device. In FIG. 17A to FIG. 21B, each of processes in another embodiment of the manufacturing method of the semiconductor device 3A (refer to FIG. 6A) is shown by a schematic perspective view which is partly broken.

First of all, as shown in FIG. 17A, a semiconductor substrate such as an n⁺-type silicon or the like is prepared. The semiconductor substrate comes to the drain region 10. Next, as shown in FIG. 17B, the mask material 80 such as a silicon oxide or the like is formed, and the trench 10t is formed in a portion in which the mask material 80 is not provided. The semiconductor substrate at the position of the trench 10t comes to the first portion 10a of the drain region 10, and the semiconductor substrate at the position of the mask material 80 comes to the second portion 10b of the drain region 10.

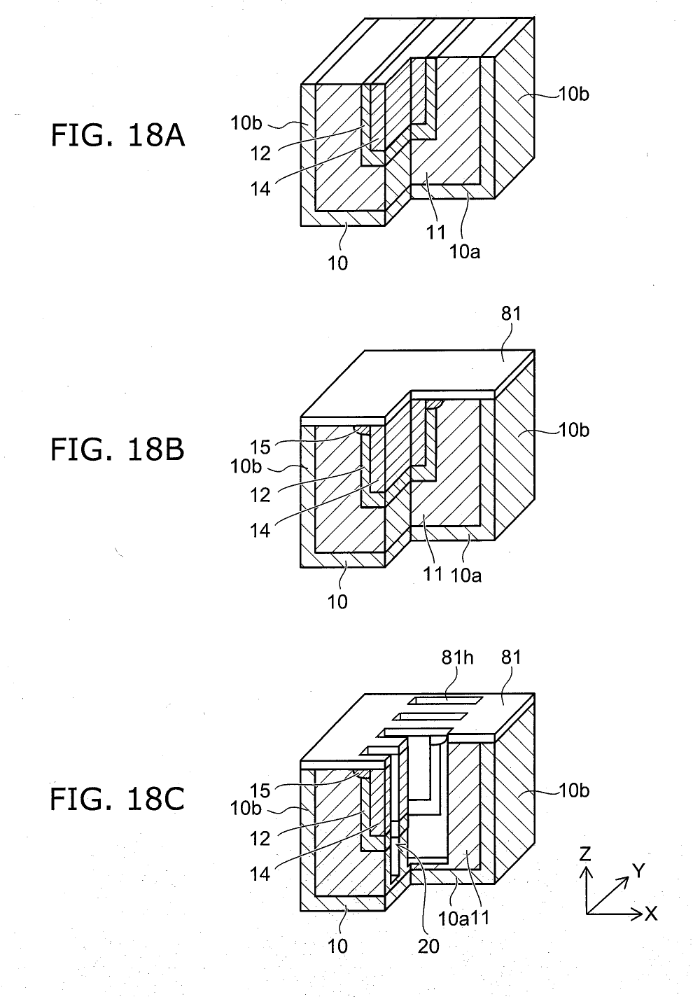

Next, as shown in FIG. 17C, the n⁻-type drift region 11, the p⁻-type base region 12 and the n⁺-type source region 14 are epitaxial grown in this order within the trench 10t. Next, as shown in FIG. 18A, each of the epitaxial grown regions is ground by the CMP or the like, and is flattened along the X-Y plane.

Next, as shown in FIG. 18B, a p⁺-type contact region 15 is formed in an upper portion of the base region 12, and a silicon oxide film 81 is thereafter formed on an upper surface. Next, as shown in FIG. 18C, an opening 81h is formed in the silicon oxide film 81, and the trench 20 is formed via the opening 81h. The trench 20 is formed to the middle of the drift region 11 from the opening 81h.

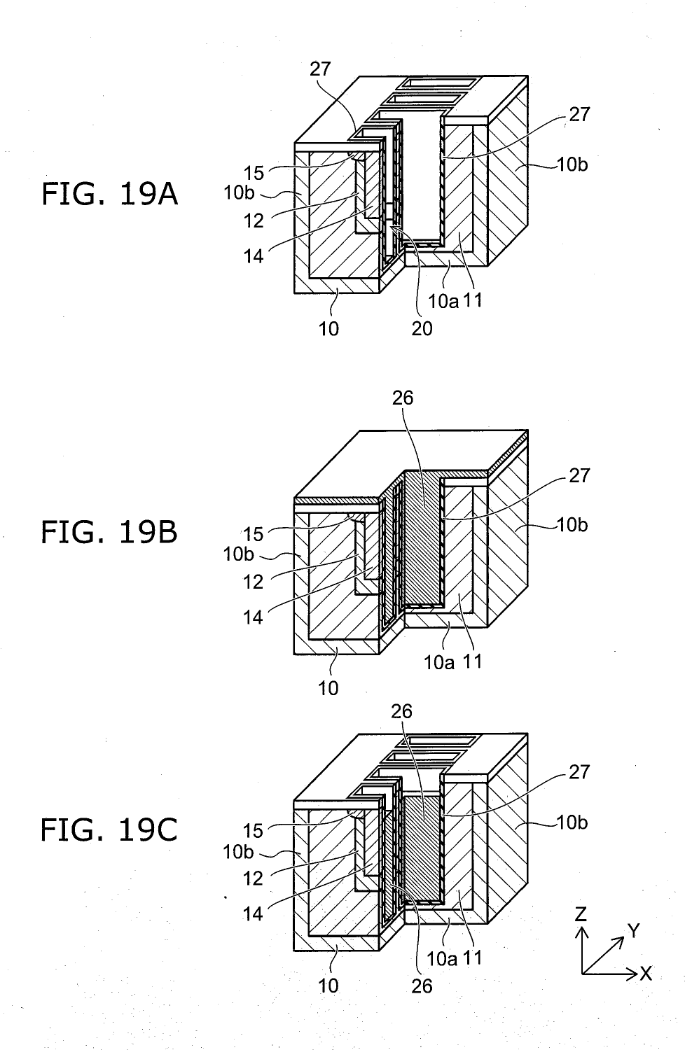

Next, as shown in FIG. 19A, the field plate insulating film 27 made of the silicon oxide or the like is formed in the inner wall of the trench 20. Next, as shown in FIG. 19B, the field plate electrode 26 made of the polysilicon or the like is formed via the field plate insulating film 27 within trench 20.

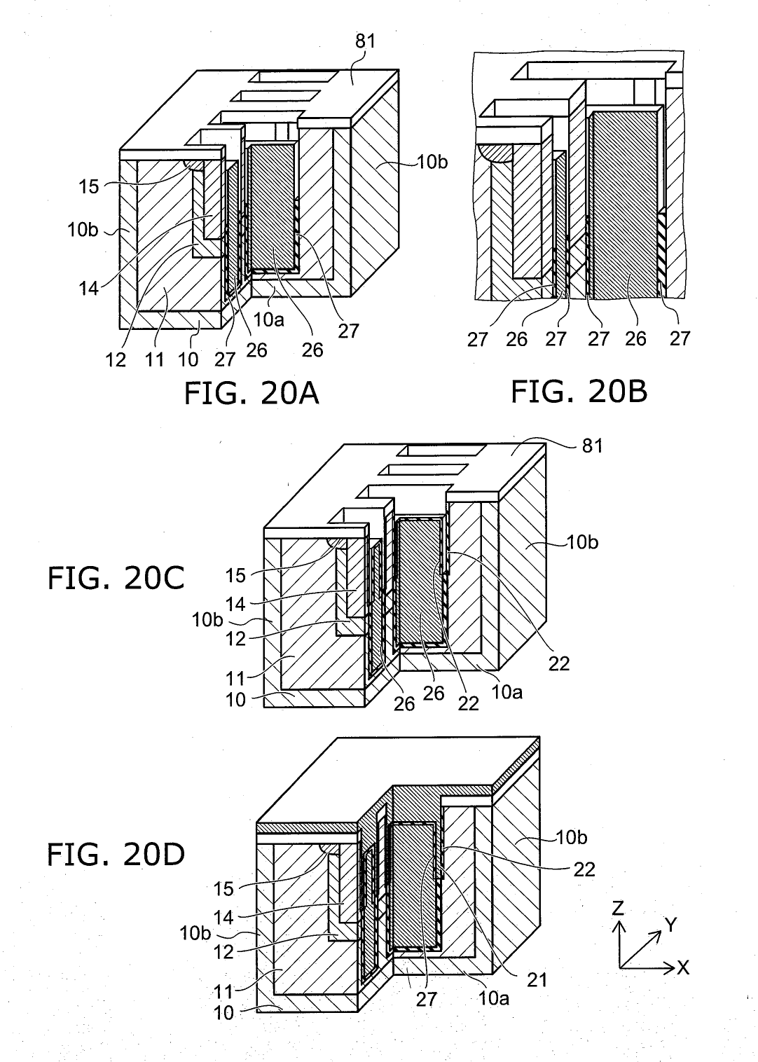

Next, as shown in FIG. 19C, the field plate electrode 26 is etched back. As a result of etch back, the upper end of the field plate electrode 26 comes to a position which is lower than the upper end of the source region 14. Next, as shown in FIGS. 20A and 20B, the field plate insulating film 27 is etched back. FIG. 20B is a schematic perspective view which enlarges a part of FIG. 20A. According to the etch back, the upper end of the field plate insulating film 27 comes to a position which is lower than the upper end of the field plate electrode 26. In this case, the position of the upper end of the field plate insulating film 27 may be shallower or deeper than a boundary position between the source region 14 and the base region 12.

Next, as shown in FIG. 20C, the gate insulating film 22 is formed in such a manner as to come into contact with the source region 14 which is exposed by the etch back of the field plate insulating film 27. Next, as shown in FIG. 20D, the gate electrode 21 made of the polysilicon or the like is formed between the gate insulating film 22 and the field plate insulating film 27.

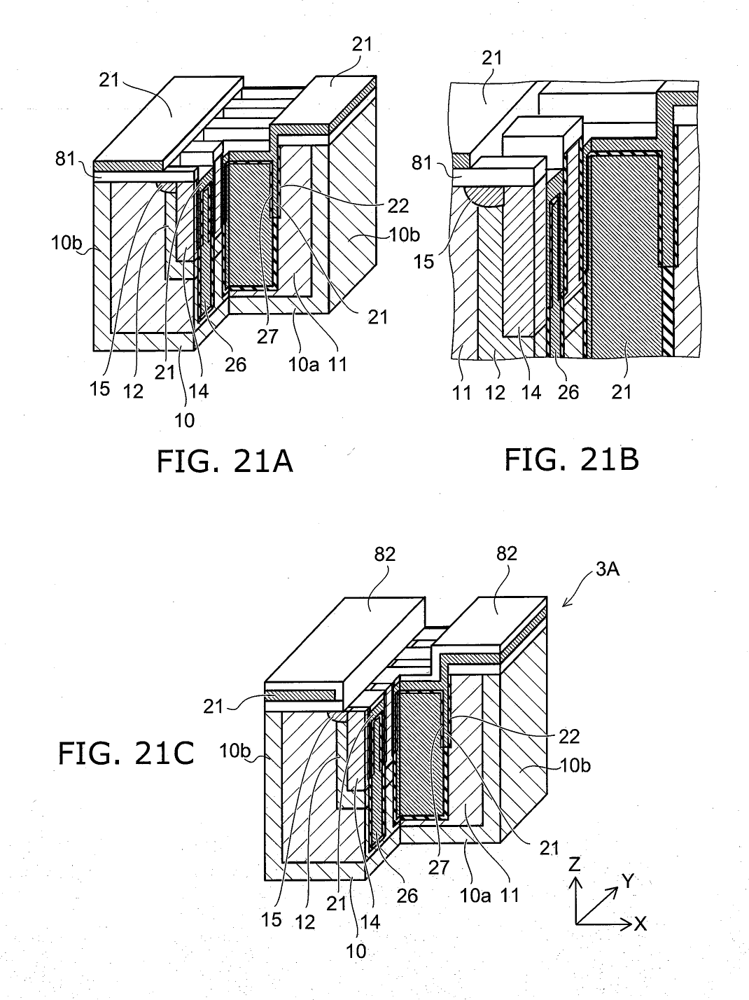

Next, as shown in FIGS. 21A and 21B, the polysilicon or the like which is the material of the gate electrode 21 is etched back. FIG. 21B is a schematic perspective view in which a part of FIG. 21A is enlarged. The gate electrode 21 between the silicon oxide films 81 is exposed by the etch back. Next, as shown in FIG. 21C, after the insulating film 82 is formed on the gate electrode 21, the contact of the source region 12 is formed.

Thereafter, the source electrode (not illustrated) connected to the source region 12 and the drain electrode (not illustrated) connected to the drain region 10 are formed. As a result, the semiconductor device 3A is completed.

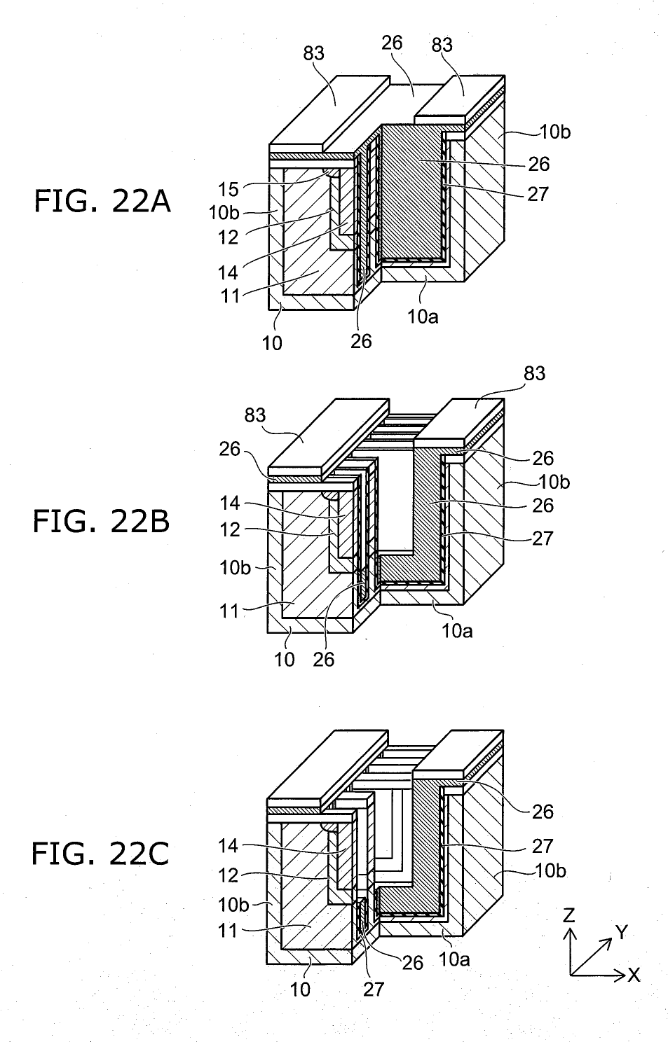

FIG. 22A to FIG. 24B are schematic perspective views illustrating a manufacturing method (fourth one) of a semiconductor device according to an embodiment.

In FIG. 22A to FIG. 24B, each of processes of the manufacturing method according to the variation (the semiconductor device 3A′) of the semiconductor device 3A (refer to FIG. 6A) is shown by a schematic perspective view which is partly broken.

In this case, the processes in FIGS. 17A to 19B in the manufacturing method (third one) of the semiconductor device 3A which is previously described are the same in the manufacturing method (fourth one) of the semiconductor device 3A′.

Next, as shown in FIG. 22A, a mask material 83 made of the silicon oxide or the like is formed on the field plate electrode 26. Next, as shown in FIG. 22B, the polysilicon or the like which is the material of the field plate electrode 26 is etched back via the mask material 83. As a result of etch back, the position of the etch back upper surface of the field plate electrode 26 comes to a lower side than the lower portion of the base region 12.

Next, as shown in FIG. 22C, the field plate insulating film 27 is etched back. As a result of etch back, the upper end of the field plate insulating film 27 comes to a position which is lower than the etch back upper surface of the field plate electrode 26. The position of the upper end of the field plate insulating film 27 may be shallower or deeper than the boundary position between the source region 14 and the base region 12.

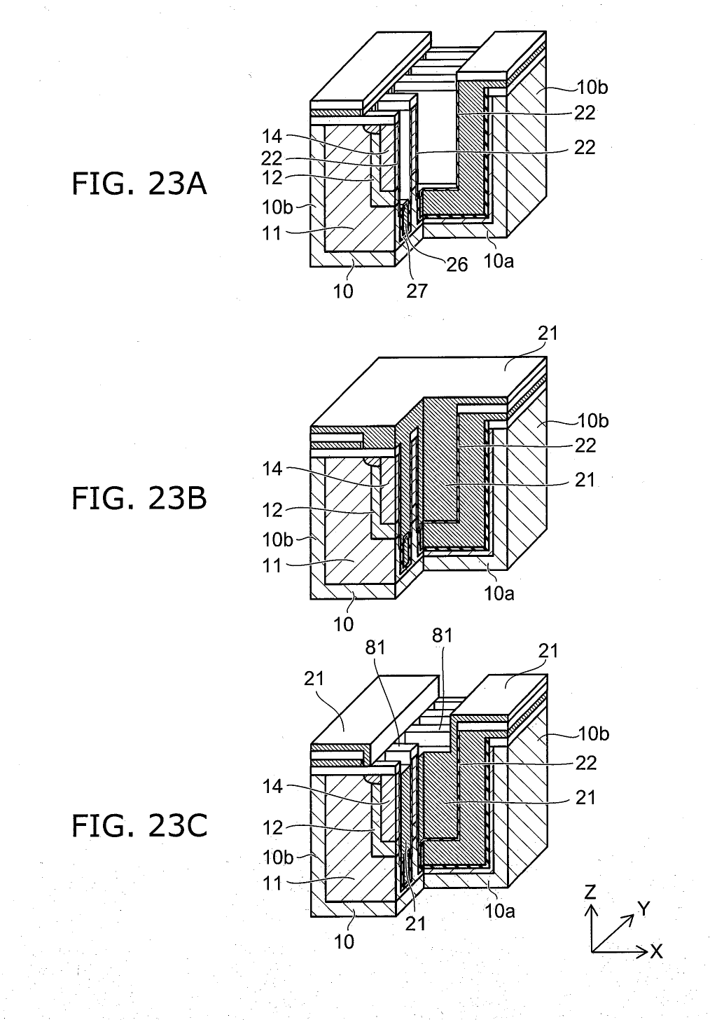

Next, as shown in FIG. 23A, the gate insulating film 22 is formed in such a manner as to come into contact with the source region 14 which is exposed by the etch back of the field plate insulating film 27. Next, as shown in FIG. 23B, the gate electrode 21 made of the polysilicon or the like is formed between the gate insulating film 22 and the field plate insulating film 27.

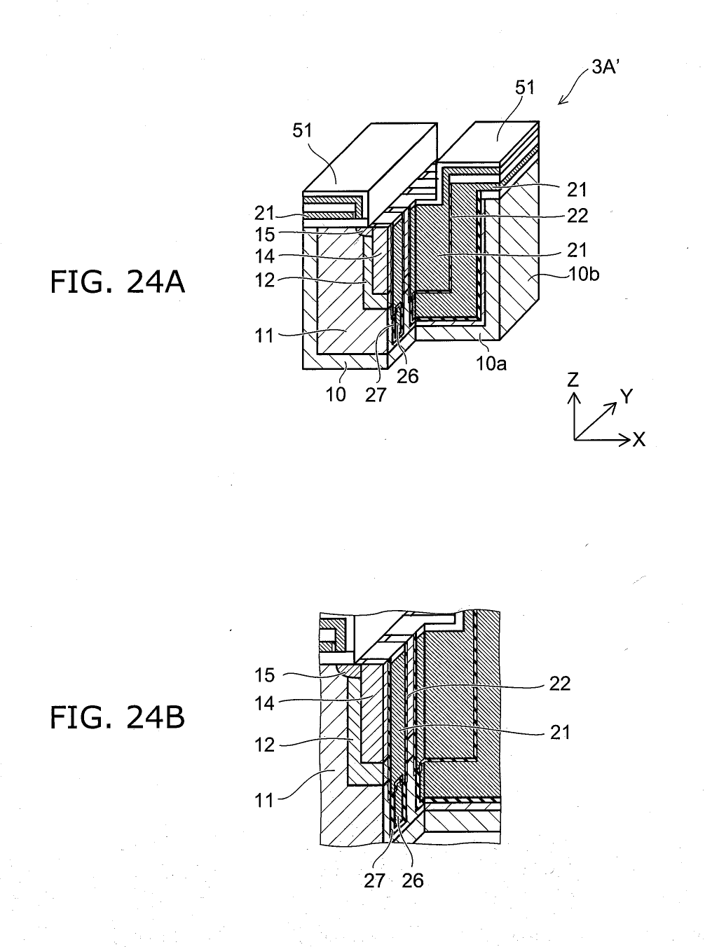

Next, as shown in FIG. 23C, the polysilicon or the like which is the material of the gate electrode 21 is etched back. According to the etch back, the gate electrode 21 between the silicon oxide films 81 is exposed. Next, as shown in FIGS. 24A and 24B, after forming the insulating film 82 on the gate electrode 21, the contact of the source region 12 is formed. FIG. 24B is a schematic perspective view in which a part of FIG. 24A is enlarged.

Thereafter, the source electrode 51 connected to the source region 12 and the drain electrode (not illustrated) connected to the drain region 10 are formed. As a result, the semiconductor device 3A′ is completed.

### Tenth Embodiment

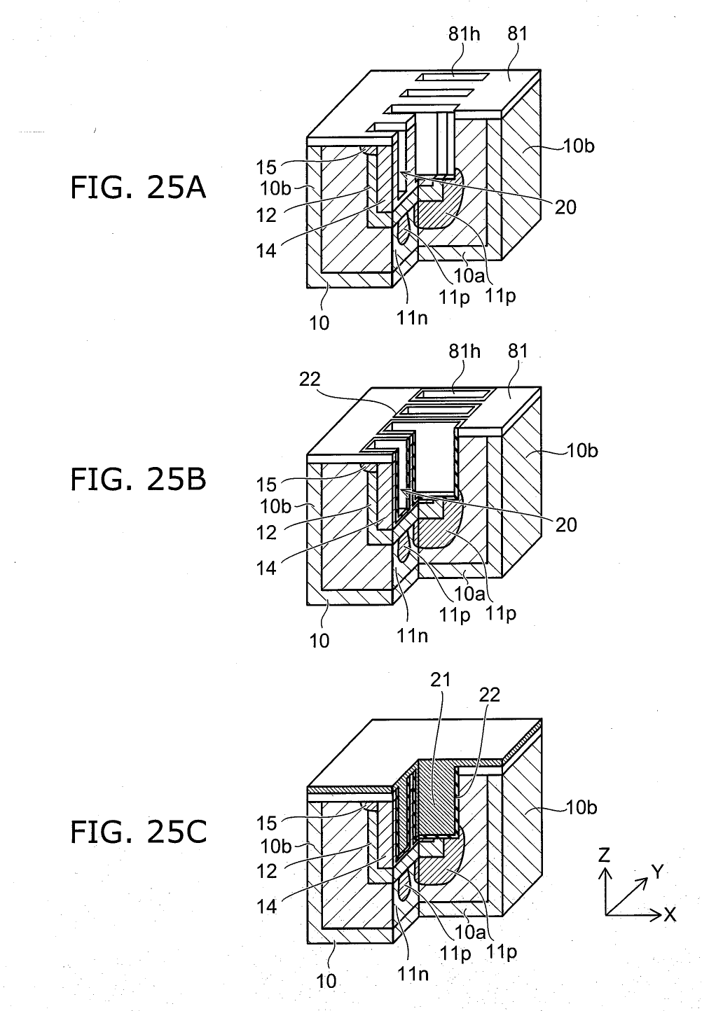

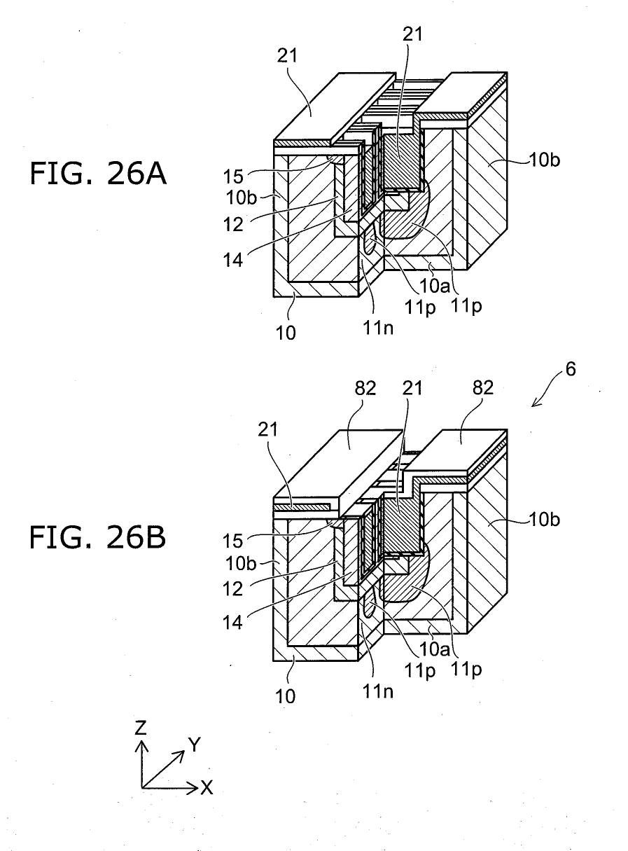

FIG. 25A to FIG. 26B are schematic perspective views illustrating a manufacturing method (fifth one) of a semiconductor device according to an embodiment.

In FIG. 25A to FIG. 26B, each of processes of the manufacturing method according to the semiconductor device 6 (refer to FIG. 10) is shown by a schematic perspective view which is partly broken.

In this case, the processes in FIGS. 11A to 12C in the manufacturing method (first one) of the semiconductor device which is previously described are the same in the manufacturing method (fifth one) of the semiconductor device.

Next, as shown in FIG. 25A, the p-type dopant (for example, the boron) is ion implanted from the opening of the trench 20 toward the bottom portion. As a result, the p⁻ region 11p is formed in the drift region 11 below the trench 20. The pitch of the p⁻ region 11p becomes the same as the pitch of the trench 20. On the other hand, the portion in which the p⁻ region 11p is not formed in the drift region 11 comes to the n⁻ region 11n. As a result, in the drift region 11, there is formed the super junction configuration in which the n⁻ region 11n and the p⁻ region 11p are alternately provided.

Next, as shown in FIG. 25B, the gate insulating film 22 made of the silicon oxide or the like is formed in the inner wall of the trench 20. Next, as shown in FIG. 25C, the gate electrode 21 made of the polysilicon or the like is formed via the gate insulating film 22 within the trench 20.

Next, as shown in FIG. 26A, the polysilicon or the like which is the material of the gate electrode 21 is etched back. According to the etch back, the gate electrode 21 between the silicon oxide films 81 is exposed. Next, as shown in FIG. 26B, after forming the insulating film 82 on the gate electrode 21, the contact of the source region 12 is formed.

Thereafter, the source electrode (not illustrated) connected to the source region 12 and the drain electrode (not illustrated) connected to the drain region 10 are formed. As a result, the semiconductor device 6 is completed.

The description is given above of the embodiment with reference to the specific examples. However, the embodiment is not limited to the specific examples. In other words, even if those skilled in the art appropriately apply design changes to the specific examples, they are included in the scope of the embodiment as long as they are provided with the features of the embodiment. Each of the elements, the arrangement, the material, the condition, the shape, the size and the like with which each of the specific examples mentioned above is provided are not limited to the exemplified one, but can be appropriately changed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a drain region of a first conductivity type which has a first portion, and a second portion having a surface extending in a first direction which is vertical to a main surface of the first portion;
a source region of the first conductivity type which extends in a second direction which is parallel to the second portion, and is provided to be spaced from the drain region;
a base region of a second conductivity type which is provided between the drain region and the source region so as to be in contact with the source region;
a drift region of the first conductivity type which is provided between the drain region and the base region;
a gate electrode which extends in the first direction and a third direction which is vertical to the first direction and the second direction, and passes through the base region in the third direction;
a gate insulating film which is provided between the source region, the base region and the drift region, and the gate electrode;
a first semiconductor region which is provided between the gate insulating film and the drain region, and has a lower impurity concentration than the drift region;
a drain electrode which is connected to the drain region; and
a source electrode which is connected to the source region and the base region.

2. The device according to claim 1, wherein the first semiconductor region is provided in such a manner as to cover an end portion in a side of the first portion of the gate insulating film, and an end portion in a side of the first portion of the base region.

3. The device according to claim 1, wherein the first semiconductor region includes an impurity element of the first conductivity type, and
wherein a concentration of the impurity element of the first conductivity type in the first semiconductor region is lower than a concentration of the impurity element of the first conductivity type in the drift region.

4. The device according to claim 1, wherein the first semiconductor region includes an impurity element of the second conductivity type, and
a concentration of the impurity element of the second conductivity type in the first semiconductor region is lower than a concentration of the impurity element of the second conductivity type in the base region.

5. A semiconductor device comprising:
a drain region of a first conductivity type which has a first portion, and a second portion having a surface extending in a first direction which is vertical to a main surface of the first portion;
a source region of the first conductivity type which extends in a second direction which is parallel to the second portion, and is provided so as to be spaced from the drain region;
a base region of a second conductivity type which is provided between the drain region and the source region so as to be in contact with the source region;
a drift region of the first conductivity type which is provided between the drain region and the base region;
a gate electrode which extends in the first direction and a third direction which is vertical to the first direction and the second direction, and passes through the base region in the third direction;
a gate insulating film which is provided between the source region, the base region and the drift region, and the gate electrode;
a field plate configuration portion which is provided between the gate insulating film and the drain region;
a drain electrode which is connected to the drain region; and
a source electrode which is connected to the source region and the base region,
wherein the field plate configuration portion includes:
a first field plate electrode which is provided between the gate electrode and the first portion; and
a first field plate insulating film which is provided between the first field plate electrode and the drift region.

6. The device according to claim 5, wherein a thickness of the first field plate insulating film is thicker than a thickness of the gate insulating film.

7. The device according to claim 5, wherein a part of the first field plate electrode laps over a part of the gate electrode, as seen in the second direction.

8. The device according to claim 5, wherein the first field plate electrode is spaced from the gate electrode in the first direction.

9. The device according to claim 5, wherein the field plate configuration portion includes:
a second field plate electrode which is provided between the gate electrode and the second portion; and
a second field plate insulating film which is provided between the second field plate electrode and the drift region.

10. The device according to claim 5, wherein the field plate configuration portion includes:
a third field plate electrode which is provided between the base region and the second portion; and
a third field plate insulating film which is provided between the third field plate electrode and the drift region.

11. The device according to claim 5, further comprising a first semiconductor region which is provided between the gate insulating film and the drain region, and has a lower impurity concentration than the drift region.

12. The device according to claim 11, wherein the first semiconductor region is provided in such a manner as to cover an end portion in a side of the first portion of the gate insulating film and an end portion in a side of the first portion of the base region.

13. The device according to claim 11, wherein the first semiconductor region includes an impurity element of the first conductivity type, and
wherein a concentration of the impurity element of the first conductivity type in the first semiconductor region is lower than a concentration of the impurity element of the first conductivity type in the drift region.

14. The device according to claim 11, wherein the first semiconductor region includes an impurity element of the second conductivity type, and
wherein a concentration of the impurity element of the second conductivity type in the first semiconductor region is lower than a concentration of the impurity element of the second conductivity type in the base region.
